(19) United States
(12) Patent Application Publication
(10) Pub. No.: US 2025/0172725 A1
(43) Pub. Date: May 29, 2025

(54) EASILY-ADHESIVE LAYER-INCLUDING POLYESTER FILM, OPTICAL LAMINATE PROVIDED WITH SAID POLYESTER FILM, AND POLARIZING PLATE, SURFACE PLATE, IMAGE DISPLAY PANEL, AND IMAGE DISPLAY DEVICE PROVIDED WITH SAID OPTICAL LAMINATE

(71) Applicant: DAI NIPPON PRINTING CO., LTD., Tokyo (JP)

(72) Inventors: Shosei KUBOTA, Kashiwa-shi, Chiba (JP); Minoru KATO, Okayama-shi, Okayama (JP); Hikaru HOTTA, Tsukuba-shi, Ibaraki (JP); Yoshiko TANAKA, Tokorozawa-shi, Saitama (JP); Takashi KURODA, Moriya-shi, Ibaraki (JP); Akinobu USHIYAMA, Moriya-shi, Ibaraki (JP)

(21) Appl. No.: 18/841,917

(22) PCT Filed: Mar. 1, 2023
(86) PCT No.: PCT/JP2023/007698

§ 371 Date: Aug. 27, 2024

(30) Foreign Application Priority Data
Mar. 2, 2022 (JP) 2022-032124

(51) Int. Cl. G02B 1/14; C09J 7/25; G02B 1/04

(52) U.S. Cl. CPC G02B 1/14; C09J 7/255; G02B 1/04; C09J 2301/122; C09J 2301/312; C09J 2301/416; C09J 2467/00

(57) ABSTRACT

Provided is an easily-adhesive layer-including polyester film such that an optical laminate including, in sequence, a polyester film with a high pencil hardness, an easily-adhesive layer, and a functional layer can achieve favorable adhesion. This easily-adhesive layer-including polyester film comprises an easily-adhesive layer on a polyester film, wherein the polyester film has a pencil hardness of B or higher, and an average value of δq/δa on a surface of the easily-adhesive layer is 1.60 or less, wherein δa is the arithmetic mean value of phase signals on a surface of the easily-adhesive layer and δq is the root-mean-square of the phase signals on the surface of the easily-adhesive layer.

### TECHNICAL FIELD

The present disclosure relates to an easily-adhesive layer-including polyester film, an optical laminate provided with the polyester film, and a polarizing plate, a surface plate, and an image display device provided with the optical laminate.

### BACKGROUND ART

Various types of optical laminates are placed in image display devices such as liquid crystal display devices, organic EL display devices, micro-LED display devices, mini-LED display devices, quantum dot-using display devices, and laser hologram display devices for the purpose of improving the visibility of images, preventing scratches on the device surface, and so on. In addition, optical laminates may also be placed on the surfaces of show windows and covers for paintings and others for the purpose of improving the visibility of articles, protecting articles, and so on. Such optical laminates often include, as a component, a functional layer on a plastic film. Triacetyl cellulose films with low optical anisotropy have been preferably used as plastic films for optical laminates. As used herein, the “triacetyl cellulose film” is sometimes referred to as a “TAC film”.

However, TAC films have problems in dimensional stability and mechanical strength, and the above problems are especially noticeable in large-screen image display devices.

For this reason, polyester films such as polyethylene terephthalate films have been proposed as an alternative to the TAC films. As used herein, the “polyethylene terephthalate film” is sometimes referred to as a “PET film”.

Meanwhile, when PET films are applied to image display devices that output polarized light, such as liquid crystal display devices and organic EL display devices, the in-plane phase difference of the PET film causes a rainbow-like interference pattern called rainbow unevenness, which unfortunately reduces the visibility.

As a countermeasure against the rainbow unevenness, a method to significantly increase the in-plane phase difference of PET film has been proposed (e.g., PTL1).

PET films with a significantly increased in-plane phase difference, such as those in PTL1, are obtained by uniaxial stretching of PET films. However, the uniaxially stretched films have problems such as a tendency to tear in the stretching direction.

In contrast to PTL1, as a countermeasure against the rainbow unevenness, a method to reduce the in-plane phase difference of PET film has been considered.

### CITATION LIST

### Patent Literature

PTL1: JP 2011-107198 A
PTL2: JP 2012-32819 A
PTL3: JP 2016-6530 A

### SUMMARY OF INVENTION

### Technical Problem

PET films with a small in-plane phase difference can be obtained, for example, by decreasing the stretching ratio. However, the PET films with a decreased stretching ratio suffer from irregular orientation in the thickness direction and accordingly a decrease in pencil hardness, and are therefore unfortunately vulnerable to scratching.

In addition, PET films with a small in-plane phase difference are also exemplified in PTL2 and PTL3. The PET films in PTL2 and PTL3 have reduced difference in stretching ratio between the MD direction that is the flow direction and the TD direction that is the width direction, for example, and thus have a reduced in-plane phase difference compared with general-purpose biaxially stretched PET films.

PET films with a reduced in-plane phase difference without decrease in the stretching ratio, such as those in PTL2 and PTL3, can easily have a high pencil hardness. Such biaxially stretched PET films with a high pencil hardness have poor adhesion to an easily-adhesive layer. Thus, optical laminates with a functional layer formed on an easily-adhesive layer on the biaxially stretched PET film with a high pencil hardness have a problem that the PET film and the easily-adhesive layer are easily detached from each other at the interface. The above problem can be solved by applying an easily-adhesive layer made of a material with excellent adhesiveness. However, this solution is not practical because the range of selection of materials for the easily-adhesive layer is limited and the product design is restricted. In addition, in the case of optical design of the optical laminate as a whole, the presence of an easily-adhesive layer made of a specific material on the PET film imposes restrictions on a material for the functional layer to be formed on the easily-adhesive layer.

The purpose of the present disclosure is to provide an easily-adhesive layer-including polyester film such that an optical laminate including, in sequence, a polyester film with a high pencil hardness, an easily-adhesive layer, and a functional layer can achieve favorable adhesion. Another purpose of the present disclosure is to provide an optical laminate provided with the polyester film, and a polarizing plate, a surface plate, and an image display device provided with the optical laminate.

### Solution to Problem

To solve the above problems, the present disclosure provides the following [1] to [5].

[1] An easily-adhesive layer-including polyester film comprising an easily-adhesive layer on a polyester film, wherein the polyester film has a pencil hardness of B or higher, and an average value of δq/δa of a surface of the easily-adhesive layer is 1.60 or less:
<Calculation of Average Value of δq/δa>
a 10 μm×10 μm area of the surface of the easily-adhesive layer is measured using an atomic force microscope in a phase mode; a distribution of phase signal on the surface of the easily-adhesive layer is obtained from the measurement; the unit of the phase signal is [deg];
an arithmetic mean value of the phase signal as shown in Equation 1 below is denoted as δa; a root mean square of the phase signal as shown in Equation 2 below is denoted as δq;
(In Equations 1 and 2 below, in the case where the orthogonal coordinate axes X and Y are placed on the reference surface showing the average value of the phase signal, and the axis orthogonal to the reference surface is the Z axis, the surface of the phase signal is defined as f(x, y); in Equations 1 and 2 below, the sizes of the area in which δa and δq are calculated are set as Lx and Ly; in Equations 1 and 2 below, Ar=Lx×Ly);
seven 2 μm×2 μm measurement evaluation regions are selected from within the 10 μm×10 μm measurement area; δa, δq, and δq/δa are calculated for each of the seven measurement evaluation regions; and the average value of δq/δa is calculated based on the δq/δa of five locations, excluding the maximum and minimum values from the δq/δa of the seven locations.

$$\begin{matrix}[ Equation 1 ] & \\ δ a = \frac{1}{Ar} {\int }_{0}^{Lx} {\int }_{0}^{Ly} \vert f ( x , y ) \vert dxdy & Equation 1\end{matrix}$$

$$\begin{matrix}[ Equation 2 ] & \\ δ q = \sqrt{\frac{1}{Ar} {\int }_{0}^{Lx} {\int }_{0}^{Ly} {f}^{2} ( x , y ) dxdy} & Equation 2\end{matrix}$$

[2] An optical laminate comprising one or more functional layers on the easily-adhesive layer of the polyester film according to [1].
[3] A polarizing plate comprising: a polarizer; a first transparent protective plate disposed on one side of the polarizer; and a second transparent protective plate disposed on the other side of the polarizer, wherein at least one of the first transparent protective plate or the second transparent protective plate is the optical laminate according to [2], and wherein the optical laminate is arranged so that a surface on the functional layer side faces a side opposite to the polarizer.
[4] A surface plate comprising an optical laminate laminated on a resin plate or a glass plate, wherein the optical laminate is the optical laminate according to [2], and wherein the optical laminate is arranged so that a surface on the functional layer side faces a side opposite to the resin plate or the glass plate.
[5] An image display device comprising the optical laminate according to [2] arranged on a display element.

### Advantageous Effects of Invention

The easily-adhesive layer-including polyester film of the present disclosure can achieve favorable adhesion of an optical laminate including, in sequence, a polyester film with a high pencil hardness, an easily-adhesive layer, and a functional layer while a specific material is not used for the easily-adhesive layer. The optical laminate of the present disclosure can achieve favorable adhesion of the optical laminate despite the high pencil hardness of the polyester film. The polarizing plate, surface plate, and image display device of the present disclosure have an optical laminate with favorable adhesion, so that defects due to poor adhesion of the optical laminate can be suppressed.

### BRIEF DESCRIPTION OF DRAWINGS

FIG. 1 is a cross-sectional view schematically illustrating an optical laminate according to an embodiment of the present disclosure.

FIG. 2 is a schematic sectional view of a device for measuring an erosion rate.

FIG. 3 is a diagram that depicts the state of abrasion of a polyester film by using a test solution containing pure water and spherical silica as jetted from a jetting section.

FIG. 4 is a diagram that illustrates an example of how to select multiple 10 μm×10 μm measurement areas.

### DESCRIPTION OF EMBODIMENTS

The following describes an easily-adhesive layer-including polyester film, an optical laminate, a polarizing plate, a surface plate, and an image display device of the present disclosure.

Note that the notation of the numerical value range “AA to BB” herein means “AA or more and BB or less”.

### [Optical Laminate]

An easily-adhesive layer-including polyester film of the present disclosure comprises an easily-adhesive layer on a polyester film, wherein the polyester film has a pencil hardness of B or higher, and an average value of δq/δa of a surface of the easily-adhesive layer is 1.60 or less:

<Calculation of Average Value of δq/δa>
a 10 μm×10 μm area of the surface of the easily-adhesive layer is measured using an atomic force microscope in a phase mode; a distribution of phase signal on the surface of the easily-adhesive layer is obtained from the measurement; the unit of the phase signal is [deg];
an arithmetic mean value of the phase signal as shown in Equation 1 below is denoted as δa; a root mean square of the phase signal as shown in Equation 2 below is denoted as δq;
(In Equations 1 and 2 below, in the case where the orthogonal coordinate axes X and Y are placed on the reference surface showing the average value of the phase signal, and the axis orthogonal to the reference surface is the Z axis, the surface of the phase signal is defined as f(x, y); in Equations 1 and 2 below, the sizes of the area in which δa and δq are calculated are set as Lx and Ly; in Equations 1 and 2 below, Ar=Lx×Ly);
seven 2 μm×2 μm measurement evaluation regions are selected from within the 10 μm×10 μm measurement area; δa, δq, and δq/δa are calculated for each of the seven measurement evaluation regions; and the average value of δq/δa is calculated based on the δq/δa of five locations, excluding the maximum and minimum values from the δq/δa of the seven locations.

$$\begin{matrix}[ Equation 3 ] & \\ δ a = \frac{1}{Ar} {\int }_{0}^{Lx} {\int }_{0}^{Ly} \vert f ( x , y ) \vert dxdy & Equation 1\end{matrix}$$

$$\begin{matrix}[ Equation 4 ] & \\ δ q = \sqrt{\frac{1}{Ar} {\int }_{0}^{Lx} {\int }_{0}^{Ly} {f}^{2} ( x , y ) dxdy} & Equation 2\end{matrix}$$

### <Polyester Film>

The polyester film should have a pencil hardness of B or higher.

When the pencil hardness of the polyester film is less than B, it is easy to improve the adhesion between the polyester film and the easily-adhesive layer, which in turn makes it easy to improve the adhesion of the optical laminate as a whole. However, when the pencil hardness of the polyester film is less than B, the surface of the functional layer of the optical laminate, or the polyester film itself, is easily scratched. This is likely to decrease the quality of the optical laminate.

In the easily-adhesive layer-including polyester film of the present disclosure, the pencil hardness of the polyester film is B or higher. This can readily improve the scratch resistance of the optical laminate with a functional layer formed on the easily-adhesive layer. In addition, in the easily-adhesive layer-including polyester film of the present disclosure, although the pencil hardness of the polyester film is B or higher, δq/δa of the surface of the easily-adhesive layer shows a predetermined value, which allows to improve the adhesion of the optical laminate.

When the pencil hardness of the polyester film is B or higher, it is difficult to make better the adhesion between the polyester film and the easily-adhesive layer. The reason may be that polyester films with a high pencil hardness tend to be highly oriented, and it is difficult for the easily-adhesive layer to firmly attach to the highly oriented polyester film.

The pencil hardness of the polyester film is preferably HB or higher, and more preferably F or higher.

If the pencil hardness of the polyester film is too high, the in-plane phase difference of the polyester film tends to increase.

The in-plane phase difference of the polyester film can be reduced by reducing the difference in stretching ratio between the longitudinal and transverse directions of the polyester film. However, it is difficult for the polyester film to achieve a pencil hardness of HB or higher when the difference in stretching ratio is reduced by reducing the longitudinal and transverse stretching ratios. In addition, when the difference in stretching ratio is reduced using a stretching ratio that causes the pencil hardness to be higher than 2H, the polyester film is highly oriented on the XY plane, whereas the orientation in the Z-axis direction is low, so that the polyester film tends to be brittle in the film thickness direction. For this reason, the pencil hardness of the polyester film is preferably 2H or less.

As used herein, the pencil hardness is measured and determined by the following operations (1) to (6):

(1) A sample is prepared by cutting a polyester film to a size of 5 cm×10 cm.

(2) The polyester film is heated at 100° C. for 10 minutes, and after heating, the polyester film is allowed to stand still in an environment at 24° C. and a relative humidity of 40% or more and 60% or less for 30 minutes or more and 60 minutes or less. (Note: the polyester film should be kept clean and flat during the operation (2). For example, during heating, one end should be gripped with a gem clip and hung in an oven so that the other end is not burdened. Then, in the pencil hardness test in (3), the test should be performed at the point where the gem clip is not in contact).

(3) A pencil hardness test is conducted on the polyester film. The pencil hardness test is based on JIS K 5600-54:1999, the scratch hardness (pencil method), while the items specified in (3) through (6) are performed with modifications from the JIS regulations. In the pencil hardness test, a pencil with a given hardness is first placed at an angle of 45 degrees onto a surface of the polyester film and moved at a speed of 3.0 mm/sec under a load of 100 g, so that the load is applied to the polyester film.

(4) After applying the load to the polyester film, the sample is heated again at 100° C. for 10 minutes.

(5) Immediately after re-heating, scratches on the polyester film are visually evaluated. The environment for visual evaluation is set to 24° C. and a relative humidity of 40% or more and 60% or less.

(6) The operations (1) through (5) above are repeated five times. Of pencils that have no scratches 4 or more out of 5 times, the hardest one is defined as the pencil hardness of the polyester film being evaluated.

In the above method of measuring and determining a pencil hardness, the case where there are no scratches 4 out of 5 times at hardness B and 3 out of 5 times at hardness F is determined as hardness B.

If the polyester film has a slow axis and a fast axis, the pencil hardness is preferably B or higher in both the slow-axis and the fast-axis directions. The slow axis of a polyester film is a direction with the highest refractive index in the plane of the polyester film. The fast axis of a polyester film is a direction perpendicular to the slow axis in the plane of the polyester film.

For the polyester film, in the case where the refractive index in the direction of the slow axis in the plane of the polyester film is defined as nx, and the refractive index in the direction perpendicular to the slow axis in the same plane is defined as ny, it is preferable that nx and ny satisfy the following relationship:

nx−ny≤0.0250.

By setting the nx−ny to 0.0250 or less, it is possible to easily suppress rainbow unevenness caused by the in-plane phase difference. Depending on the design of the optical laminate, it is possible to easily suppress rainbow unevenness even when nx−ny is 0.0300 or less.

As used herein, the rainbow unevenness means rainbow unevenness as seen by the naked eye(s), unless otherwise mentioned.

The nx−ny is more preferably 0.0240 or less and further preferably 0.0230 or less.

If the nx−ny is too small, it is difficult to suppress blackout. Thus, the nx−ny is preferably 0.0050 or more, more preferably 0.0080 or more, more preferably 0.0100 or more, more preferably 0.0120 or more, and more preferably 0.0130 or more.

As used herein, the blackout means a phenomenon where the entire surface becomes dark when light passing through a polarizer and a polyester film in this order is viewed through the polarizer such as polarized sunglasses.

In the constituent features shown herein, in the case where multiple options for the upper and lower limits of each numerical value are indicated, one of the upper limit options and one of the lower limit options may be combined to provide an embodiment of the numerical range.

Examples of the embodiment of the numerical range of nx−ny include 0.0050 or more and 0.0300 or less, 0.0050 or more and 0.0250 or less, 0.0050 or more and 0.0240 or less, 0.0050 or more and 0.0230 or less, 0.0080 or more and 0.0300 or less, 0.0080 or more and 0.0250 or less, 0.0080 or more and 0.0240 or less, 0.0080 or more and 0.0230 or less, 0.0100 or more and 0.0300 or less, 0.0100 or more and 0.0250 or less, 0.0100 or more and 0.0240 or less, 0.0100 or more and 0.0230 or less, 0.0120 or more and 0.0300 or less, 0.0120 or more and 0.0250 or less, 0.0120 or more and 0.0240 or less, 0.0120 or more and 0.0230 or less, 0.0130 or more and 0.0300 or less, 0.0130 or more and 0.0250 or less, 0.0130 or more and 0.0240 or less, and 0.0130 or more and 0.0230 or less.

As used herein, the refractive indices such as nx and ny, in-plane phase difference, and phase difference in the thickness direction are assumed to mean the values at a wavelength of 550 nm unless otherwise indicated. As used herein, the term “in-plane phase difference” is sometimes denoted as “Re” and the term “phase difference in the thickness direction” is sometimes denoted as “Rth”.

The nx−ny of the polyester film, as well as the in-plane phase difference and phase difference in the thickness direction described below, can be measured or calculated using, for example, the product name “RETS-100” of OTSUKA ELECTRONICS CO., LTD. The nx−ny can be calculated if there is information on the thickness of the polyester film, in addition to the measurement results of in-plane phase difference obtained by using the “RETS-100”. The phase difference in the thickness direction can be calculated if there is information on the thickness of the polyester film and information on the average refractive index, in addition to the measurement results of in-plane phase difference obtained by using the “RETS-100” (for example, the average refractive index of polyethylene terephthalate is known to be 1.617, and this value is used herein for calculation).

The thickness of the polyester film can be measured as follows.

(1) For a polyester film having, for instance, an easily-adhesive layer and a functional layer, a sample with an exposed cross-section of the polyester film is first prepared to enable cross-sectional observation. A microtome is used to prepare the sample. Examples of the microtome include those manufactured by Leica. The thickness of the polyester film can then be measured by observing the cross section with a scanning electron microscope. Examples of the scanning electron microscope include “Model No. S4800” manufactured by Hitachi, Ltd.

(2) The thickness of the polyester film without any easily-adhesive layer or functional layer can be measured by a film thickness meter. Examples of the film thickness meter include Nikon Corporation's product name “Digimicro”. For Nikon Corporation's product name “Digimicro”, “MS-5C”+“MH-15M” is preferably used for the “stand”+“main unit,” and “TC-101A” for the “counter”.

As used herein, the nx−ny, Re, and Rth each mean the average value of measurements at three locations, excluding the minimum and maximum values from measurements at five locations, unless otherwise noted.

As used herein, the five measurement locations should be selected from five arbitrary locations that are free from defects such as deformation, scratches, and stains.

As used herein, the atmosphere in which the various parameters are measured should be at a temperature of 23° C.±5C and a relative humidity of 40% or more and 65% or less, unless otherwise noted. In addition, unless otherwise noted, samples should be exposed to the atmosphere for 30 minutes or more and 60 minutes or less before each measurement.

The various parameters include, for example, nx−ny, Re, Rth, δa, δq, total light transmittance, and haze.

The polyester film preferably has other properties, such as an in-plane phase difference and a phase difference in the thickness direction, within the following ranges.

As used herein, the in-plane phase difference and the phase difference in the thickness direction mean those calculated by the equations below. The “T” in the following equations means the thickness of the polyester film.

$$In - plane phase difference ( Re ) = ( nx - ny ) \times T [ nm ]$$

$$Phase difference in the thickness direction ( Rth ) = ( ( nx + ny ) / 2 - nz ) \times T [ nm ]$$

### —In-Plane Phase Difference (Re)—

The polyester film has an in-plane phase difference of preferably 1200 nm or less, more preferably 1148 nm or less, more preferably 1100 nm or less, more preferably 1000 nm or less, and more preferably 950 nm or less. By setting the in-plane phase difference to 1200 nm or less, rainbow unevenness can be easily suppressed.

The rainbow unevenness can also be suppressed by adjusting the functional layer and light source. There are also some applications where rainbow unevenness is not considered important. Therefore, the in-plane phase difference of the polyester film is not limited to 1200 nm or less, but may be more than 1200 nm.

The polyester film has an in-plane phase difference of preferably 50 nm or more, more preferably 100 nm or more, more preferably 150 nm or more, more preferably 200 nm or more, more preferably 250 nm or more, more preferably 300 nm or more, more preferably 400 nm or more, more preferably 450 nm or more, and more preferably 497 nm or more.

By setting the in-plane phase difference to 50 nm or more, blackout can be easily suppressed. This is because the polyester film with an average in-plane phase difference of less than 50 nm hardly disrupts linearly polarized light, therefore the linearly polarized light passes therethrough as it is, while the polyester film with an average in-plane phase difference of 50 nm or more may disrupt the linearly polarized light. Note that in order to facilitate a good pencil hardness of polyester film, the in-plane phase difference is preferably 520 nm or more, and more preferably 620 nm or more.

Examples of an embodiment of the preferable rage of the in-plane phase difference include 50 nm or more and 1200 nm or less, 50 nm or more and 1148 nm or less, 50 nm or more and 1100 nm or less, 50 nm or more and 1000 nm or less, 50 nm or more and 950 nm or less, 100 nm or more and 1200 nm or less, 100 nm or more and 1148 nm or less, 100 nm or more and 1100 nm or less, 100 nm or more and 1000 nm or less, 100 nm or more and 950 nm or less, 150 nm or more and 1200 nm or less, 150 nm or more and 1148 nm or less, 150 nm or more and 1100 nm or less, 150 nm or more and 1000 nm or less, 150 nm or more and 950 nm or less, 200 nm or more and 1200 nm or less, 200 nm or more and 1148 nm or less, 200 nm or more and 1100 nm or less, 200 nm or more and 1000 nm or less, 200 nm or more and 950 nm or less, 250 nm or more and 1200 nm or less, 250 nm or more and 1148 nm or less, 250 nm or more and 1100 nm or less, 250 nm or more and 1000 nm or less, 250 nm or more and 950 nm or less, 300 nm or more and 1200 nm or less, 300 nm or more and 1148 nm or less, 300 nm or more and 1100 nm or less, 300 nm or more and 1000 nm or less, 300 nm or more and 950 nm or less, 400 nm or more and 1200 nm or less, 400 nm or more and 1148 nm or less, 400 nm or more and 1100 nm or less, 400 nm or more and 1000 nm or less, 400 nm or more and 950 nm or less, 450 nm or more and 1200 nm or less, 450 nm or more and 1148 nm or less, 450 nm or more and 1100 nm or less, 450 nm or more and 1000 nm or less, 450 nm or more and 950 nm or less, 497 nm or more and 1200 nm or less, 497 nm or more and 1148 nm or less, 497 nm or more and 1100 nm or less, 497 nm or more and 1000 nm or less, and 497 nm or more and 950 nm or less.

### —Phase Difference in the Thickness Direction (Rth)—

The phase difference in the thickness direction of the polyester film is preferably 2000 nm or more, more preferably 3000 nm or more, further preferably 4000 nm or more, and even more preferably 5000 nm or more.

By setting the phase difference in the thickness direction of the polyester film to 2000 nm or more, blackouts not only in the frontal direction but also when viewed from an oblique direction can be easily suppressed.

In order to make it easier to set the Re/Rth to the below-described range, the phase difference in the thickness direction of the polyester film is preferably 15000 nm or less, more preferably 12000 nm or less, and further preferably 9000 nm or less.

Examples of an embodiment of the preferable range of the phase difference in the thickness direction include 2000 nm or more and 15000 nm or less, 2000 nm or more and 12000 nm or less, 2000 nm or more and 9000 nm or less, 3000 nm or more and 15000 nm or less, 3000 nm or more and 12000 nm or less, 3000 nm or more and 9000 nm or less, 4000 nm or more and 15000 nm or less, 4000 nm or more and 12000 nm or less, 4000 nm or more and 9000 nm or less, 5000 nm or more and 15000 nm or less, 5000 nm or more and 12000 nm or less, and 5000 nm or more and 9000 nm or less.

### —Re/Rth—

A small Re/Rth means that the degree of stretching of the polyester film is closer to even biaxiality. Thus, by setting the Re/Rth to 0.20 or less, the pencil hardness of the polyester film can be easily improved. In addition, by setting the Re/Rth to 0.20 or less, it can be easy to suppress the occurrence of adverse effects on visibility as caused by wrinkles in the polyester film due to environmental changes. In order to facilitate demonstration of the effect of setting the Re/Rth to a given range, the in-plane phase difference of the polyester film is preferably in the above range. The Re/Rth is more preferably 0.20 or less, more preferably 0.17 or less, and more preferably 0.15 or less.

If the Re/Rth is too small, the film tends to be highly oriented in the XY-plane, while less oriented in the Z-axis direction, resulting in brittleness in the film thickness direction. Thus, if the Re/Rth is too small, the polyester film may break when the polyester film is attached to an adherend or when the polyester film is peeled off from an adherend. Therefore, the polyester film has Re/Rth of preferably 0.01 or more, more preferably 0.03 or more, more preferably 0.05 or more, and more preferably 0.06 or more.

Examples of an embodiment of the preferable range of the Re/Rth include 0.01 or more and 0.20 or less, 0.01 or more and 0.17 or less, 0.01 or more and 0.15 or less, 0.03 or more and 0.20 or less, 0.03 or more and 0.17 or less, 0.03 or more and 0.15 or less, 0.05 or more and 0.20 or less, 0.05 or more and 0.17 or less, 0.05 or more and 0.15 or less, 0.06 or more and 0.20 or less, 0.06 or more and 0.17 or less, and 0.06 or more and 0.15 or less.

### —Haze, Total Light Transmittance—

The polyester film has a JIS K7136.2000 haze of preferably 3.0% or less, more preferably 2.0/6 or less, and further preferably 1.0% or less.

In addition, the polyester film has a JIS K7361-1:1997 total light transmittance of preferably 80% or more, more preferably 85% or more, and further preferably 90% or more.

### —UV Light Transmittance—

The polyester film has a light transmittance at a wavelength of 380 nm of preferably 20% or less, and more preferably 10% or less.

### <Erosion Rate>

The polyester film preferably has an E₀₋₂₀ of 1.4 μm/g or more when E₀₋₂₀ is defined as the average erosion rate from the surface of the polyester film to a depth of 20 μm.

As used herein, E₀₋₂₀ is measured under the following measurement conditions.

### <Measurement Conditions>

A test solution is prepared by mixing pure water, dispersion, and spherical silica with an average particle size within ±8% of 4.2 μm as a reference at a mass ratio of 968:2:30, and is then put into a container. The test solution in the container is sent to a nozzle. Compressed air is sent into the nozzle to accelerate the test solution within the nozzle, and a predetermined amount of the test solution is jetted perpendicularly onto the polyester film through a jet hole at the tip of the nozzle. This causes the spherical silica in the test solution to collide with the polyester film. The cross-sectional shape of the nozzle is set to 1 mm×1 mm square, and the distance between the jet hole and the polyester film is set to 4 mm. Meanwhile, the flow rates of the test solution and the compressed air supplied to the nozzle, the pressure of the compressed air, and the pressure of the test solution in the nozzle should be predetermined values adjusted by the calibration described below.

After a predetermined amount of the test solution is jetted, the jetting of the test solution is temporarily stopped.

After the jetting of the test solution is temporarily stopped, the cross-sectional profile of the polyester film where the spherical silica in the test solution has collided is measured.

An operation with one cycle consisting of three steps including: a step of jetting a predetermined amount of the test solution from the jet hole; a step of temporarily stopping the jetting of the test solution after the predetermined amount of the test solution is jetted; and a step of measuring the cross-sectional profile after the jetting of the test solution is temporarily stopped is repeated until the depth of the cross-sectional profile exceeds 20 μm. The erosion rates (μm/g) of the polyester films up to a depth of 20 μm in the cross-sectional profile for each cycle are calculated. The erosion rates of the polyester films up to a depth of 20 μm in the cross-sectional profile for each cycle are averaged to calculate the E₀₋₂₀.

### <Calibration>

The test solution is put into the container. The test solution in the container is sent to the nozzle. Compressed air is sent into the nozzle to accelerate the test solution within the nozzle, and an arbitrary amount of the test solution is jetted perpendicularly onto an acrylic plate with a thickness of 2 mm through a jet hole at the tip of the nozzle. This causes the spherical silica in the test solution to collide with the acrylic plate. The cross-sectional shape of the nozzle is set to 1 mm×1 mm square, and the distance between the jet hole and the acrylic plate is set to 4 mm.

After an arbitrary amount of the test solution is jetted, the jetting of the test solution is temporarily stopped. After the jetting of the test solution is temporarily stopped, the cross-sectional profile of the acrylic plate where the spherical silica in the test solution has collided is measured.

The erosion rate (μm/g) of the acrylic plate is calculated by dividing the depth (μm) of the cross-sectional profile by the arbitrary amount (g).

The erosion rate of the acrylic plate of 5% based on 1.88 (μm/g) is set as the acceptance condition, and calibration is performed by adjusting the flow rate of the test solution and compressed air, the pressure of the compressed air, and the pressure of the test solution in the nozzle so that the erosion rate of the acrylic plate is in the range described above.

Hereinafter, the measurement conditions of the erosion rate and the technical significance of the erosion rate calculated using the measurement conditions are explained with reference to FIG. 2. Examples of the device for measuring the erosion rate as shown in FIG. 2 include an MSE tester, product number “MSE-A203”, of Palmeso Co., Ltd.

As for the conditions for measuring erosion rate of the present disclosure, first, a test solution is prepared by mixing pure water, a dispersant, and spherical silica with an average particle size within ±8% of 4.2 μm as a reference at a mass ratio of 968:2:30, and is then put into a container (11). In the container (11), the test solution preferably be stirred.

The dispersant is not particularly limited as long as the spherical silica can be dispersed. Examples of the dispersant include the product name “DEMOL N” of Wako Pure Chemical Industries, Ltd.

In other words, the wording “average particle size within ±8% of 4.2 μm as a reference” means that the average particle size is 3.864 μm or more and 4.536 μm or less.

Meanwhile, in the measurement conditions of erosion rate herein, the “average particle size of spherical silica” is measured as the volume-averaged value d50 in the particle size distribution measurement by laser light diffractometry (so-called “median diameter”).

In the results of the particle size distribution measurement of the spherical silica, upon normalizing the maximum frequency of the particle size to 100, the range of particle size with a frequency of 50 is preferably within ±10% of 4.2 μm as a reference. The phrase “range of particle size with a frequency of 50” is expressed as “X−Y (μm)” while “X” is defined as the particle size with a frequency of 50 and is positioned in a more plus direction than the particle size with a frequency of 100 and “Y” is defined as the particle size with a frequency of 50 and is positioned in a more minus direction than the particle size with a frequency of 100. Note that as used herein, the “range of particle size with a frequency of 50” is sometimes referred to as the “full width at half maximum of the particle size distribution”.

Examples of the spherical silica with an average particle size within ±8% of 4.2 μm as a reference include model number “MSE-BS-5-3” designated by Palmeso Co., Ltd. Examples of the spherical silica corresponding to the model number “MSE-BS-5-3” designated by Palmeso Co., Ltd. include the product number “BS5-3” of Potters-Ballotini Co., Ltd.

The test solution in the container is fed into a nozzle (51). The test solution may, for example, be sent to the nozzle through piping for test solution (21). Between the container (11) and the nozzle (51), a flow meter (31) for measuring the flow rate of the test solution is preferably disposed. The flow rate of the test solution should be a value adjusted by the above-mentioned calibration.

Note that in FIG. 2, the nozzle (51) is located inside a housing (52) that constitutes a jetting section (50).

Compressed air is sent the nozzle (51). The compressed air is sent to the nozzle, for example, through a compressed air line (22). The position in the nozzle where the compressed air is fed into is preferably upstream of the position where the test solution is fed into. The upstream is the side far from the nozzle's jet hole.

A flow meter (32) for measuring the flow rate of the compressed air and a pressure gauge (42) for measuring the pressure of the compressed air are preferably installed, before the compressed air arrives at the nozzle (51). The compressed air may be supplied using, for instance, an air compressor, not shown.

The flow rate and the pressure of the compressed air should each be a value adjusted by the above-mentioned calibration.

When the compressed air is sent into the nozzle (51), the test solution is accelerated while being mixed by the compressed air. The accelerated test solution is then jetted through the jet hole at the tip of the nozzle (51) and impacts perpendicularly against a polyester film (70). The polyester film is mainly abraded by spherical silica particles in the test solution.

Note that the inside of the nozzle (51) is preferably provided with a pressure gauge (41) for measuring the pressure of the test solution in the nozzle. The pressure gauge (41) is preferably provided downstream of the position where the compressed air is fed into and the position where the test solution is fed into.

The pressure of the test solution in the nozzle (51) should be a value adjusted by the above-mentioned calibration.

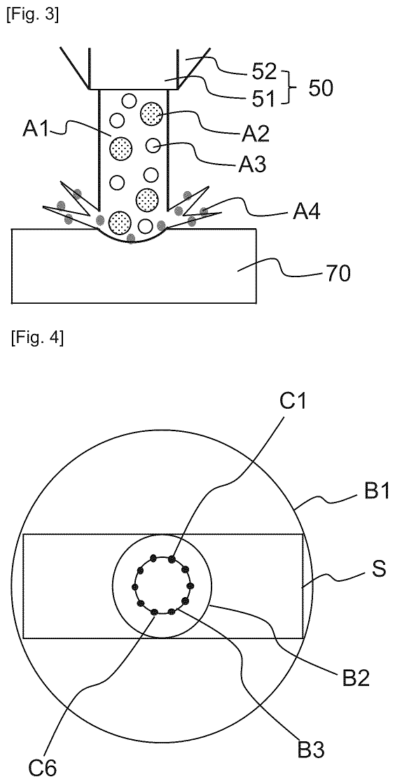

The test solution jetted through the jet hole at the tip of the nozzle (51) is mixed with air and then sprayed. This can lower the impact pressure of spherical silica particles on the polyester film. Thus, the amount of abrasion of the polyester film by one spherical silica particle can be reduced to a small amount. FIG. 3 is a diagram that depicts the state of abrasion of the polyester film (70) by using a test solution containing pure water (A1) and spherical silica (A2) as jetted from the jetting section (50). In FIG. 3, reference sign A3 denotes air and reference sign A4 denotes an abraded polyester film.

In addition, the test solution contains water, which has an excellent cooling effect. This can practically eliminate deformation and degeneration of the polyester film as caused by heat at the time of impact. In other words, abnormal abrasion of the polyester film can be substantially eliminated. In addition, the water also plays a role in cleaning the abraded polyester film surface and achieving stable abrasion. Further, the water also plays a role in accelerating the spherical silica particles and controlling the fluid of the test solution.

Furthermore, since a huge number of spherical silica particles collide with the polyester film, the influence of subtle differences in physical properties of individual spherical silica particles can be eliminated.

Moreover, for the measurement conditions of the present disclosure, by setting the flow rate of the test solution supplied to the nozzle, the flow rate of the compressed air supplied to the nozzle, the pressure of the compressed air supplied to the nozzle, and the pressure of the test solution in the nozzle to values adjusted by the above-mentioned calibration, setting the cross-sectional shape of the nozzle to a square of 1 mm×1 mm, and setting the distance between the jet hole and the polyester film to 4 mm, elements having an influence on the amount of abrasion of the polyester film are identified. Note that the distance is denoted by “d” in FIG. 2, and means the vertical distance between the nozzle tip, namely the jet hole, and the polyester film.

From the above, it can be said that the measurement conditions of the present disclosure are those that enable the formation of statistically stable abrasion marks on the polyester film.

The polyester film (70) may be attached to a sample mount (81) of a measuring device (90). It is preferable to mount the plastic film (70) on the sample mount (81) via a support (82) such as a stainless steel plate.

The test solution jetted onto the polyester film (70) preferably be collected in a receptor (12) and returned to the container (11) through a return piping (23). A return pump (24) is preferably disposed between the receptor (12) and the return piping (23).

The measurement conditions of the present disclosure require that the jetting of the test solution is temporarily stopped after the jetting of a predetermined amount of the test solution, and that the cross-sectional profile of the polyester film where the spherical silica in the test solution has collided is measured after the jetting of the test solution is temporarily stopped.

The cross-sectional profile means the cross-sectional shape of the polyester film abraded by the test solution. The polyester film is mainly abraded by spherical silica particles in the test solution.

The cross-sectional profile may be measured for example, by a cross-sectional profile acquisition unit (60) such as a stylus-type surface profilometer or a laser interferometry-type surface profilometer. Note that the cross-sectional profile acquisition unit (60) is usually located at a position away from the polyester film (70) when the test solution is jetted. For this reason, it is preferable that at least one of the polyester film (70) or the cross-sectional profile acquisition unit (60) is movable.

Palmeso Co., Ltd.'s MSE tester, product number “MSE-A203”, uses a stylus method for measuring a cross-sectional profile.

Further, under the measurement conditions of the present disclosure, an operation with one cycle consisting of three steps including: a step of jetting a predetermined amount of test solution from the jet hole; a step of temporarily stopping the jetting of the test solution after the predetermined amount of the test solution is jetted; and a step of measuring a cross-sectional profile after the jetting of the test solution is temporarily stopped, is repeated until the depth of the cross-sectional profile exceeds 20 μm.

By performing this operation, the erosion rate of the polyester film at each cycle can be measured, and further, variations of the erosion rate of the polyester film can be calculated.

The above cycle may also be continued after the depth of the cross-sectional profile exceeds 20 μm, but it is preferable to terminate the cycle when the depth of the cross-sectional profile exceeds 20 μm. Meanwhile, the reason why the measurement is limited to the “depth of 20 μm from the surface of the polyester film” is that the fact was taken into account that the physical properties of the polyester film tend to fluctuate at or near the surface, while they tend to be more stable as the site gets into a deeper portion.

As used herein, the erosion rate at each cycle can be calculated by dividing the depth (μm) of cross-sectional profile having progressed at each cycle by the amount (g) of test solution jetted in each cycle. The depth (μm) of cross-sectional profile at each cycle is the depth at the deepest position of cross-sectional profile at each cycle.

The amount of the test solution jetted in each cycle is, in principle, a “fixed quantity”, but it may vary slightly in each cycle.

The amount of the test solution jetted in each cycle is not particularly limited, but the lower limit is preferably 0.5 g or larger and more preferably 1.0 g or larger, and the upper limit is preferably 3.0 g or less and more preferably 2.0 g or less.

Under the measurement conditions of the present disclosure, the erosion rates (μm/g) up to a depth of 20 μm in the cross-sectional profile for each cycle are calculated. Then, the erosion rates up to a depth of 20 μm in the cross-sectional profile for each cycle are averaged to calculate E₀₋₂₀ (the average erosion rate from the surface of the polyester film to a depth of 20 μm).

The above cycle is repeated until the depth of the cross-sectional profile exceeds 20 μm. Here, the data obtained at the cycle with a cross-sectional profile depth of more than 20 μm is excluded from the data for calculating E₀₋₂₀.

In general, polyester films are more easily scratched if they are soft and less easily scratched if they are hard. The present inventors considered using, as an index of pencil hardness, the values obtained from evaluations using a picodentor in the depth direction (e.g., Martens hardness, indentation hardness, elastic recovery work). Unfortunately, the above-described parameters such as Martens hardness, indentation hardness, and elastic recovery work were sometimes unable to be used as an index of pencil hardness.

In addition, the polyester film when stretched tends to have increased strength. Specifically, uniaxially stretched polyester films tend to have better pencil hardness than unstretched polyester films; and biaxially stretched polyester films tend to have better pencil hardness than uniaxially stretched polyester films. However, there were cases where pencil hardness was not sufficient even for biaxially stretched polyester films.

The present inventors examined the erosion rate as an index of pencil hardness of the polyester film. As mentioned above, polyester films are more easily scratched if they are soft and less easily scratched if they are hard. Therefore, it is considered that a smaller erosion rate can improve the pencil hardness. However, the present inventors have, instead, found that by increasing the erosion rate (E₀₋₂₀) to 1.4 μm/g or more, the polyester film can achieve favorable pencil hardness. The present inventors have also found that the erosion rate of the polyester film tends to be larger for biaxially stretched polyester films than for uniaxially stretched polyester films, and that whether the pencil hardness of biaxially stretched polyester film is favorable or not can be determined by the erosion rate.

The reason why the erosion rate of the polyester film correlates with pencil hardness may be as follows.

As described above, under the measurement conditions of the present disclosure, the test solution containing water and spherical silica is mixed with air and then sprayed. This can lower the impact pressure of spherical silica particles on the polyester film. Accordingly, in the case of a soft polyester film, the stresses caused by the spherical silica colliding with the polyester film are easily dispersed. This seems to cause the polyester film to be less prone to abrasion, resulting in a low erosion rate. By contrast, in the case of a hard polyester film, the stresses caused by the spherical silica colliding with the polyester film are not easily dispersed. This seems to cause the polyester film to be more prone to abrasion, resulting in a high erosion rate.

Different erosion rates in biaxially stretched polyester films seems to be caused by the difference in the degree of elongation of molecular chains, the difference in the degree of molecular orientation, etc. For example, in biaxially stretched polyester films, the molecules are, in principle, stretched in-plane. However, there may be some molecules that are not sufficiently stretched locally in the plane. As the percentage of molecules that are not sufficiently stretched locally in the plane increases, it is expected that the biaxially stretched polyester film becomes locally softer and the erosion rate decreases. In addition, even biaxially stretched polyester films with comparable in-plane phase differences are considered to exhibit different erosion rates due to differences in local molecular orientation.

The E₀₋₂₀ is preferably 1.4 μm/g or more, more preferably 1.5 μm/g or more, more preferably 1.6 μm/g or more, more preferably 1.78 μm/g or more, more preferably 1.8 μm/g or more, more preferably 1.9 μm/g or more, and more preferably 2.0 μm/g or more in order to obtain favorable pencil hardness of the polyester film.

The E₀₋₂₀ is preferably 3.0 μm/g or less, more preferably 2.5 μm/g or less, more preferably 2.2 μm/g or less, and more preferably 2.07 μm/g or less in order to make the polyester film less susceptible to cracking.

Examples of the embodiment of a preferable range of E₀₋₂₀ of the polyester film include 1.4 μm/g or more and 3.0 μm/g or less, 1.4 μm/g or more and 2.5 μm/g or less, 1.4 μm/g or more and 2.2 μm/g or less, 1.4 μm/g or more and 2.07 μm/g or less, 1.5 μm/g or more and 3.0 μm/g or less, 1.5 μm/g or more and 2.5 μm/g or less, 1.5 μm/g or more and 2.2 μm/g or less, 1.5 μm/g or more and 2.07 μm/g or less, 1.6 μm/g or more and 3.0 μm/g or less, 1.6 μm/g or more and 2.5 μm/g or less, 1.6 μm/g or more and 2.2 μm/g or less, 1.6 μm/g or more and 2.07 μm/g or less, 1.78 μm/g or more and 3.0 μm/g or less, 1.78 μm/g or more and 2.5 μm/g or less, 1.78 μm/g or more and 2.2 μm/g or less, 1.78 μm/g or more and 2.07 μm/g or less, 1.8 μm/g or more and 3.0 μm/g or less, 1.8 μm/g or more and 2.5 μm/g or less, 1.8 μm/g or more and 2.2 μm/g or less, and 1.8 μm/g or more and 2.07 μm/g or less.

Before the erosion rate described above is measured, the above-mentioned calibration should be performed.

The calibration can be conducted as follows.

### <Calibration>

The test solution is put into the container. The test solution in the container is sent to the nozzle. Compressed air is sent into the nozzle to accelerate the test solution within the nozzle, and an arbitrary amount of the test solution is jetted perpendicularly onto an acrylic plate with a thickness of 2 mm through a jet hole at the tip of the nozzle. This causes the spherical silica in the test solution to collide with the acrylic plate. The cross-sectional shape of the nozzle is set to 1 mm×1 mm square, and the distance between the jet hole and the acrylic plate is set to 4 mm.

After an arbitrary amount of the test solution is jetted, the jetting of the test solution is temporarily stopped. After the jetting of the test solution is temporarily stopped, the cross-sectional profile of the acrylic plate where the spherical silica in the test solution has collided is measured.

The erosion rate (μm/g) of the acrylic plate is calculated by dividing the depth (μm) of the cross-sectional profile by the arbitrary amount (g).

The erosion rate of the acrylic plate of ±5% based on 1.88 (μm/g) is set as the acceptance condition, and calibration is performed by adjusting the flow rate of the test solution and compressed air, the pressure of the compressed air, and the pressure of the test solution in the nozzle so that the erosion rate of the acrylic plate is in the range described above.

The test solution used in the calibration should be the same as the test solution used in the measurement conditions to be implemented later.

The measuring device used in the calibration should be the same as the measuring device used in the measurement conditions to be implemented later.

The difference between the calibration and the measurement conditions to be implemented later is, for example, the use of a 2 mm-thick acrylic plate, which is a standard sample, as a sample in the calibration, whereas a polyester film is used as a sample in the measurement conditions.

The 2 mm-thick acrylic plate, which is a standard sample, is preferably a polymethyl methacrylate plate (PMMA plate). The 2 mm-thick acrylic plate, which is a standard sample, preferably has an AcE of 1.786 μm/g or more and 1.974 μm/g or less, when the average erosion rate of acrylic plate measured under the following measurement conditions A is defined as AcE. Here, examples of the spherical silica under the following measurement conditions A include model number “MSE-BS-5-3” designated by Palmeso Co., Ltd. Examples of the spherical silica corresponding to the model number “MSE-BS-5-3” designated by Palmeso Co., Ltd. include the product number “BS5-3” of Potters-Ballotini Co., Ltd.

### <Measurement Conditions A>

A test solution is prepared by mixing pure water, a dispersant, and spherical silica with an average particle size within ±8% of 4.2 μm as a reference at a mass ratio of 968:2:30, and is then put into a container. The test solution in the container is sent to a nozzle. Compressed air is sent into the nozzle to accelerate the test solution within the nozzle, and a predetermined amount of the test solution is jetted perpendicularly onto the acrylic plate through a jet hole at the tip of the nozzle. This causes the spherical silica in the test solution to collide with the acrylic plate. The cross-sectional shape of the nozzle is set to 1 mm×1 mm square, and the distance between the jet hole and the acrylic plate is set to 4 mm. Meanwhile, the flow rates of the test solution and the compressed air supplied to the nozzle, the pressure of the compressed air, and the pressure of the test solution in the nozzle are such that the flow rate of the test solution is 100 ml/min or more and 150 ml/min or less, the flow rate of the compressed air is 4.96 L/min or more and 7.44 L/min or less, the pressure of the compressed air is 0.184 MPa or more and 0.277 MPa or less, and the pressure of the test solution in the nozzle is 0.169 MPa or more and 0.254 MPa or less.

After 4 g of the test solution is jetted, the jetting of the test solution is temporarily stopped.

After the jetting of the test solution is temporarily stopped, the cross-sectional profile of the acrylic plate where the spherical silica in the test solution has collided is measured.

The erosion rate AcE (unit is “μm/g”) of the acrylic plate is calculated by dividing the depth (μm) of the cross-sectional profile by the amount (4 g) of the test solution jetted.

If the erosion rate of the acrylic plate is within the range of ±5% of 1.88 (μm/g) as a reference, the test is passed. Meanwhile, during calibration, an operation to adjust the flow rates of the test solution and the compressed air, the pressure of the compressed air, and the pressure of the test solution in the nozzle is performed so that the erosion rate of the acrylic plate is within the range.

Note that the “erosion rate is ±5% of 1.88 (μm/g) as a reference” means, in other words, that the erosion rate is 1.786 (μm/g) or more and 1.974 (μm/g) or less.

<σ₀₋₂₀/E₀₋₂₀>

The polyester film preferably has a σ₀₋₂₀/E₀₋₂₀ of 0.100 or less when a variation in the erosion rate as calculated from the erosion rate from the surface of the polyester film to a depth of 20 μm is defined as σ₀₋₂₀.

As used herein, σ₀₋₂₀ can be calculated from the erosion rates up to a depth of 20 μm in the cross-sectional profile for each cycle under the above measurement conditions.

Here, σ₀₋₂₀/E₀₋₂₀ indicates the coefficient of variation of the erosion rate, and a small value of σ₀₋₂₀/E₀₋₂₀ means that the erosion rate is less likely to vary in the thickness direction of the polyester film. By setting the σ₀₋₂₀/E₀₋₂₀ to 0.100 or less, the erosion rate in the thickness direction is stabilized and better pencil hardness can be easily obtained.

The upper limit of σ₀₋₂₀/E₀₋₂₀ is more preferably 0.080 or less, still more preferably 0.077 or less, still more preferably 0.070 or less, still more preferably 0.060 or less, and still more preferably 0.055 or less.

The lower limit of σ₀₋₂₀/E₀₋₂₀ is not particularly limited, and is usually 0.020 or greater, preferably 0.035 or greater, and more preferably 0.040 or greater. In addition, the polyester film may be weakly stretched when the value of σ₀₋₂₀/E₀₋₂₀ is low. Weakly stretched polyester films tend to have poor solvent resistance, be easily broken, and have low stability against heat and humidity. Thus, the σ₀₋₂₀/E₀₋₂₀ preferably be 0.020 or greater.

Examples of an embodiment of the preferable range of the σ₀₋₂₀/E₀₋₂₀ include 0.020 or more and 0.100 or less, 0.020 or more and 0.080 or less, 0.020 or more and 0.077 or less, 0.020 or more and 0.070 or less, 0.020 or more and 0.060 or less, 0.020 or more and 0.055 or less, 0.035 or more and 0.100 or less, 0.035 or more and 0.080 or less, 0.035 or more and 0.077 or less, 0.035 or more and 0.070 or less, 0.035 or more and 0.060 or less, 0.035 or more and 0.055 or less, 0.040 or more and 0.100 or less, 0.040 or more and 0.080 or less, 0.040 or more and 0.077 or less, 0.040 or more and 0.070 or less, 0.040 or more and 0.060 or less, and 0.040 or more and 0.055 or less.

### —Thickness—

In order to improve the mechanical strength, the thickness of the polyester film is preferably 10 μm or more, more preferably 21 μm or more, further preferably 25 μm or more, and even more preferably 30 μm or more. In addition, by setting the thickness of the polyester film to 10 μm or more, stress that may occur when another member comes into contact with a side opposite to the functional layer of the optical laminate can be unlikely to propagate to the interface between the polyester film and the easily-adhesive layer.

In order to reduce the in-plane phase difference and to improve the bending resistance, the thickness of the polyester film is preferably 75 μm or less, more preferably 60 μm or less, further preferably 55 μm or less, and even more preferably 50 μm or less.

Examples of an embodiment of the preferable range of the thickness of the polyester film include 10 μm or more and 75 μm or less, 10 μm or more and 60 μm or less, 10 μm or more and 55 μm or less, 10 μm or more and 50 μm or less, 21 μm or more and 75 μm or less, 21 μm or more and 60 μm or less, 21 μm or more and 55 μm or less, 21 μm or more and 50 μm or less, 25 μm or more and 75 μm or less, 25 μm or more and 60 μm or less, 25 μm or more and 55 μm or less, 25 μm or more and 50 μm or less, 30 μm or more and 75 μm or less, 30 μm or more and 60 μm or less, 30 μm or more and 55 μm or less, and 30 μm or more and 50 μm or less.

### <<Raw Materials>>

Examples of a polyester constituting the polyester film include: a homopolymer obtained from polycondensation of a dicarboxylic acid with a diol; a copolymer obtained from polycondensation of one or more dicarboxylic acids and two or more diols; a copolymer obtained from polycondensation of two or more dicarboxylic acids and one or more diols; and a blended resin obtained by mixing one or more homopolymers and one or more copolymers.

As long as the effects of the present disclosure are not inhibited, the polyester film may contain an additive(s) such as a UV absorber, easy-lubricating particles such as inorganic particles, heat-resistant polymer particles, an alkali metal compound, an alkaline earth metal compound, a phosphorus compound, an antistatic agent, a light retardant, a flame retardant, a heat stabilizer, an antioxidant, an anti-gelling agent, and a surfactant.

The raw material(s) of the polyester film may be newly synthesized, naturally derived, or recycled.

Examples of the dicarboxylic acid include terephthalic acid, isophthalic acid, orthophthalic acid, 2,5-naphthalenedicarboxylic acid, 2,6-naphthalenedicarboxylic acid, 1,4-naphthalenedicarboxylic acid, 1,5-naphthalenedicarboxylic acid, diphenylcarboxylic acid, diphenoxyethanedicarboxylic acid, diphenylsulfonic carboxylic acid, anthracenedicarboxylic acid, 1,3-cyclopentanedicarboxylic acid, 1,3-cyclohexanedicarboxylic acid, 1,4-cyclohexanedicarboxylic acid, hexahydroterephthalic acid, hexahydroisophthalic acid, malonic acid, dimethylmalonic acid, succinic acid, 3,3-diethylsuccinic acid, glutaric acid, 2,2-dimethylglutaric acid, adipic acid, 2-methyladipic acid, trimethyladipic acid, pimelic acid, azelaic acid, dimeric acid, sebacic acid, suberic acid, and dodecanedicarboxylic acid.

Examples of the diol include ethylene glycol, propylene glycol, hexamethylene glycol, neopentyl glycol, 1,2-cyclohexanedimethanol, 1,4-cyclohexanedimethanol, decamethylene glycol, 1,3-propanediol, 1,4-butanediol, 1,5-pentanediol, 1,6-hexanediol, 2,2-bis(4-hydroxyphenyl)propane, and bis(4-hydroxyphenyl)sulfone.

Among polyesters, polyethylene terephthalate is preferred in order to improve mechanical strength. That is, the polyester film preferably includes polyethylene terephthalate.

Examples of the process for polymerizing polyethylene terephthalate include: a direct polymerization method, in which terephthalic acid is reacted directly with ethylene glycol and, if necessary, other dicarboxylic acid components and diol components; and an ester exchange method, in which the dimethyl ester of terephthalic acid and ethylene glycol are subjected to an ester exchange reaction. In the ester exchange method, the dimethyl ester of terephthalic acid may contain methyl esters of other dicarboxylic acids if necessary. In the ester exchange method, ethylene glycol may contain other diol components if necessary.

The intrinsic viscosity of polyethylene terephthalate is preferably 0.45 or more and 0.70 or less. If the intrinsic viscosity is less than 0.45, the tear resistance may decrease. If the intrinsic viscosity is more than 0.70, the filtration accuracy may decrease due to a larger increase in filtration pressure.

### <<Layer Configuration>>

The polyester film may have a monolayer structure or a multilayer structure.

In the monolayer structure, stretching is easy to control. With the monolayer structure, by reducing the difference between stretching ratios in the flow direction and the width direction without decreasing the stretching ratios in the flow direction and the width direction, the polyester film easily has an increased pencil hardness. Therefore, the monolayer structure, which allows easy control of stretching, is preferred because it makes it easier to increase the pencil hardness of the polyester film. In addition, in order to control the erosion rate, it is important to stretch the molecules evenly in the plane of the polyester film. Thus, the monolayer structure is preferred because the erosion rate can be easily controlled.

On the other hand, the polyester film with a multilayer structure is preferred because it is easy to impart the effect obtained by changing the composition of each layer. For example, by making a laminated polyester film including at least three or more layers by co-extrusion, and using polyester with low oligomer content for both surface layers, the amount of oligomer precipitated after heat-treatment can be suppressed easily.

### —Stretching—

In order to increase the pencil hardness of the polyester film, it is preferable that the difference between stretching ratios in the flow direction and the width direction is reduced without decreasing the stretching ratios in the flow direction and the width direction.

The polyester film is thus preferably a stretched film, and more preferably a biaxially stretched film.

### —Sequential Biaxial Stretching—

In sequential biaxial stretching, a casting film is stretched in the flow direction, and then the film is stretched in the width direction.

The stretching in the flow direction is generally performed by the difference in peripheral speed of a pair of stretching rolls. The stretching in the flow direction may be performed in one step or may be performed in multiple steps using a plurality of stretching roll pairs. In order to suppress excessive variations in optical properties such as in-plane phase difference, it is preferable to bring a plurality of nip rolls close to the stretching rolls. The stretching ratio in the flow direction is generally twice or more and 15 times or less and is preferably twice or more and 7 times or less, more preferably 3 times or more and 5 times or less, further preferably 3 times or more and 4 times or less, in order to suppress excessive variations in optical properties such as in-plane phase difference.

The stretching temperature is preferably the glass transition temperature of the resin or more and the glass transition temperature+100° C. or less in order to suppress excessive variations in physical properties such as in-plane phase difference. In the case of PET, 70° C. or more and 120° C. or less is preferable, 80° C. or more and 110° C. or less is more preferable, and 95° C. or more and 110° C. or less is further preferable.

For the stretching temperature, the average value of the in-plane phase difference tends to be small by reducing the stretching section at low temperature, for example, by rapidly raising the temperature of the film. Meanwhile, the average value of the in-plane difference tends to be large by making longer the section stretched at low temperature, for example, by slowly raising the temperature of the film, to achieve higher orientation.

Also, in stretching in the flow direction, the erosion rate tends to decrease as the stretching time is shortened and to increase as the stretching time is extended. The reason for this is thought to be that a short stretching time makes it difficult for the molecules to be stretched evenly in the plane of the polyester film, while a long stretching time makes it easier for the molecules to be stretched evenly in the plane of the polyester film. In other words, to obtain E₀₋₂₀ of 1.4 μm/g or higher, it is preferable to increase the stretching time. Further, it is easier to achieve an E₀₋₂₀ of 1.4 μm/g or higher by increasing the stretching time while suitably increasing the stretching ratio to the extent that the physical properties do not vary.

The film stretched in the flow direction may have a layer with a function such as easy-lubricating property or anti-static property formed by in-line coating or off-line coating. A layer(s) formed by in-line coating or off-line coating herein should not be counted as the number of layers constituting the polyester film.

The stretching in the width direction is generally performed with tentering by transporting the film while gripping both ends of the film with clips. The stretching ratio in the width direction is usually 2 times or more and 15 times or less, and in order to suppress excessive variations in physical properties such as in-plane phase difference, the stretching ratio is preferably 2 times or more and 7 times or less, more preferably 3 times or more and 6 times or less, and further preferably 4 times or more and 5 times or less. In addition, the stretching ratio in the width direction is preferably higher than the stretching ratio in the flow direction.

The stretching temperature is preferably the glass transition temperature of the resin or more and the glass transition temperature+120° C. or less and preferably increases from the upstream to the downstream. Specifically, when the transverse stretching section is divided into two, the difference between the upstream temperature and the downstream temperature is preferably 20° C. or more, more preferably 30° C. or more, further preferably 35° C. or more, and even more preferably 40° C. or more. Meanwhile, in the case of PET, the stretching temperature at the first step is preferably 80° C. or more and 120° C. or less, more preferably 90° C. or more and 110° C. or less, and still more preferably 95° C. or more and 105° C. or less.

The polyester film sequentially biaxially stretched as above is preferably subjected to heat-treatment in a tenter at the stretching temperature or higher and lower than the melting point, in order to provide flatness and dimensional stability. Specifically, in the case of PET, heat setting is preferably performed within the range of 150° C. or more and 255° C. or less, more preferably 200° C. or more and 250° C. or less. In addition, additional stretching of 1% or more and 10% or less is preferably performed in the first half of the heat-treatment, in order to suppress excessive variations in physical properties such as in-plane phase difference.

After heat-treatment, the polyester film is slowly cooled to room temperature and then wound up. In addition, during heat-treatment or slow cooling, relaxation treatment or the like may be used in combination, as required. The relaxation rate during heat-treatment is preferably 0.5% or more and 5% or less, more preferably 0.5% or more and 3% or less, further preferably 0.8% or more and 2.5% or less, and even more preferably 1% or more and 2% or less, in order to suppress excessive variations in physical properties such as in-plane phase difference. In addition, the relaxation rate during slow cooling is preferably 0.5% or more and 3% or less, more preferably 0.5% or more and 2% or less, further preferably 0.5% or more and 1.5% or less, and even more preferably 0.5% or more and 1.0% or less, in order to suppress excessive variations in physical properties such as in-plane phase difference. The temperature during slow cooling is preferably 80° C. or more and 150° C. or less, more preferably 90° C. or more and 130° C. or less, further preferably 100° C. or more and 130° C. or less, and even more preferably 100° C. or more and 120° C. or less, in order to facilitate improved flatness.

The transfer speed when the stretched polyester film is produced is about 100 m/s or more and 300 m/s or less.

### —Simultaneous Biaxial Stretching—

In simultaneous biaxial stretching, a casting film is guided to a simultaneous biaxial tenter and transported while gripping both ends of the film with clips, so as to be stretched simultaneously and/or stepwise in the flow and width directions. Examples of the simultaneous biaxial stretching machine include pantagraph-type, screw-type, drive motor-type, and linear motor-type. A drive motor-type or linear motor-type machine is preferable since the stretching ratio can be changed arbitrarily, and the relaxation treatment can be performed at any place.

The magnification of simultaneous biaxial stretching is generally 6 times or more and 50 times or less in terms of area magnification. The area magnification is preferably 8 times or more and 30 times or less, more preferably 9 times or more and 25 times or less, further preferably 9 times or more and 20 times or less, and even more preferably 10 times or more and 15 times or less, in order to suppress excessive variations in physical properties such as in-plane phase difference. In simultaneous biaxial stretching, the stretching ratio in the flow direction and the stretching ratio in the width direction are preferably adjusted within the range of twice or more and 15 times or less, so that the aforementioned area magnification is achieved.

In addition, in the case of simultaneous biaxial stretching, the stretching ratios in the flow and width directions are preferably almost the same, and the stretching speed in the flow and width directions are also so as to be preferably almost the same, in order to suppress the difference in orientation in the plane.

The stretching temperature in simultaneous biaxial stretching is preferably the glass transition temperature of the resin or more and the glass transition temperature+120° C. or less, in order to suppress excessive variations in physical properties such as in-plane phase difference. In the case of PET, 80° C. or more and 160° C. or less is preferable, 90° C. or more and 150° C. or less is more preferable, and 100° C. or more and 140° C. or less is further preferable.

The film simultaneously biaxially stretched is preferably subjected to heat-treatment subsequently in a heat setting chamber of the tenter at the stretching temperature or higher and lower than the melting point, in order to provide flatness and dimensional stability. The heat-treatment conditions are the same as the heat-treatment conditions after sequential biaxial stretching.

### <Easily-Adhesive Layer>

The easily-adhesive layer-including polyester film of the present disclosure should have an easily-adhesive layer. In addition, in the easily-adhesive layer-including polyester film of the present disclosure, the average value of δq/δa of the surface of the easily-adhesive layer should be 1.60 or less.

Calculation of Average Value of δq/δa—

A 10 μm×10 μm area of the surface of the easily-adhesive layer is measured using an atomic force microscope in a phase mode; a distribution of phase signal on the surface of the easily-adhesive layer is obtained from the measurement; the unit of the phase signal is [deg];
an arithmetic mean value of the phase signal as shown in Equation 1 below is denoted as δa; a root mean square of the phase signal as shown in Equation 2 below is denoted as δq;
(In Equations 1 and 2 below, in the case where the orthogonal coordinate axes X and Y are placed on the reference surface showing the average value of the phase signal, and the axis orthogonal to the reference surface is the Z axis, the surface of the phase signal is defined as f(x, y); in Equations 1 and 2 below, the sizes of the area in which δa and δq are calculated are set as Lx and Ly; in Equations 1 and 2 below, Ar=Lx×Ly);
seven 2 μm×2 μm measurement evaluation regions are selected from within the 10 μm×10 μm measurement area; δa, δq, and δq/δa are calculated for each of the seven measurement evaluation regions; and the average value of δq/δa is calculated based on the δq/δa of five locations, excluding the maximum and minimum values from the δq/δa of the seven locations.

The above seven measurement evaluation regions may partially overlap. However, the percentage of overlap between any measurement evaluation region and the other six measurement evaluation regions is preferably 25% or less, more preferably 12% or less, and further preferably 5% or less, based on the area of the measurement evaluation region.

$$\begin{matrix}[ Equation 5 ] & \\ δ a = \frac{1}{Ar} {\int }_{0}^{Lx} {\int }_{0}^{Ly} \vert f ( x , y ) \vert dxdy & Equation 1\end{matrix}$$

$$\begin{matrix}[ Equation 6 ] & \\ δ q = \sqrt{\frac{1}{Ar} {\int }_{0}^{Lx} {\int }_{0}^{Ly} {f}^{2} ( x , y ) dxdy} & Equation 2\end{matrix}$$

In the absence of an easily-adhesive layer, even if a functional layer is formed on the polyester film, it is not possible to achieve favorable adhesion of an optical laminate having a polyester film and a functional layer.

Even when an easily-adhesive layer is formed on the polyester film, with the average value of δq/δa of the surface of the easily-adhesive layer exceeding 1.60, it is not possible to achieve favorable adhesion of the optical laminate having the polyester film, the easily-adhesive layer, and the functional layer in this order.

The following describes the technical significance of the average value of δq/δa of the surface of the easily-adhesive layer.

δa and δq are parameters related to the phase signal when a given region of the surface of the easily-adhesive layer is measured using an atomic force microscope in a phase mode. The unit of the phase signal is [deg]. The above phase signal indicates the viscoelasticity of the surface of the easily-adhesive layer. The atomic force microscope is a device that measures surface physical properties by scanning the surface of a sample with a microscopic probe attached to a plate spring. In the phase mode, the changes in vibration phase in the plane can be mapped by vibrating the probe for measurement. Thus, in the phase mode, the contrast caused by the difference in viscoelasticity of the surface component can be mapped.

δa is the arithmetic mean value of the phase signals in a given region. On the other hand, δq is the root-mean-square of the phase signals in a given region. The root-mean-square emphasizes values away from the arithmetic mean value. Hence, even when the value of δa, the arithmetic mean value, is the same and when the variation of the phase signals in a given region is large, the average value of δq, the root-mean-square, becomes larger. Likewise, even when the value of δa, the arithmetic mean value, is the same and when the variation of the phase signals in a given region is large, the average value of δq/δa becomes larger. In contrast, even when the value of δa, the arithmetic mean value, is the same and when the variation of the phase signals in a given region is small, the average value of δq/δa becomes smaller. In other words, an easily-adhesive layer with a small arithmetic mean value of δq/δa indicates that the phase signals are concentrated near the arithmetic mean value of the phase signals in a given region, and that the variation of the phase signals in a given region is small. Since the phase signal indicates the viscoelasticity of the surface of the easily-adhesive layer, an easily-adhesive layer with a small average value of δq/δa indicates a small change in viscoelasticity in a given region.

Note that the phase signal indicates the relative amount of change within the same image. Thus, it is generally not possible to compare δa and δq in different samples. In the present disclosure, δq/δa, the ratio between δa and δq is noted. As mentioned above, δq/δa is a parameter that indicates the variation of phase within a sample and is a dimensionless parameter. Therefore, δq/δa can be said to be an appropriate parameter to compare the phase variation among samples.

As described above, an easily-adhesive layer with a small average value of δq/δa indicates a small change in viscoelasticity in a given region. Here, the polyester film including an easily-adhesive layer with a small average value of δq/δa can improve adhesion of an optical laminate with a functional layer formed on the easily-adhesive layer. The adhesion of an optical laminate is considered to be favorable for the following reasons.

When another member contacts with the functional layer of the optical laminate, a given stress occurs. The stress is propagated to the interface between the polyester film and the easily-adhesive layer through the functional layer and the easily-adhesive layer. The stress propagation varies depending on the value of viscoelasticity of the easily-adhesive layer. Thus, when the in-plane viscoelasticity of the easily-adhesive layer changes significantly, the magnitude of the stress propagated to the interface between the polyester film and the easily-adhesive layer varies depending on the in-plane location. Therefore, when the average value of δq/δa of the easily-adhesive layer is large, a large stress tends to be applied to a given location in the plane, and the interface delamination of the optical laminate is likely to occur. On the other hand, when the average value of δq/δa of the easily-adhesive layer is small, the stress is dispersed in the plane. This is considered to be possible to suppress the interface delamination of the optical laminate and to improve the adhesion.

The reason why the viscoelasticity of the easily-adhesive layer varies from place to place may be, for instance, the compatibility of the components constituting the easily-adhesive layer.

The average value of δq/δa is preferably 1.57 or less, more preferably 1.54 or less, more preferably 1.536 or less, more preferably 1.50 or less, more preferably 1.45 or less, and more preferably 1.40 or less.

A smaller average value of δq/δa means more even viscoelasticity of the surface of the easily-adhesive layer. If the surface viscoelasticity of the easily-adhesive layer is too even, it may be difficult for the components of the functional layer to soak into the easily-adhesive layer, and the adhesion between the easily-adhesive layer and the functional layer may be difficult to improve. Therefore, the average value of δq/δa is preferably 1.125 or more, more preferably 1.20 or more, more preferably 1.25 or more, more preferably 1.30 or more, and more preferably 1.326 or more.

Examples of an embodiment of the preferable range of the average value of δq/δa include 1.125 or more and 1.60 or less, 1.125 or more and 1.57 or less, 1.125 or more and 1.54 or less, 1.125 or more and 1.536 or less, 1.125 or more and 1.50 or less, 1.125 or more and 1.45 or less, 1.125 or more and 1.40 or less, 1.20 or more and 1.60 or less, 1.20 or more and 1.57 or less, 1.20 or more and 1.54 or less, 1.20 or more and 1.536 or less, 1.20 or more and 1.50 or less, 1.20 or more and 1.45 or less, 1.20 or more and 1.40 or less, 1.25 or more and 1.60 or less, 1.25 or more and 1.57 or less, 1.25 or more and 1.54 or less, 1.25 or more and 1.536 or less, 1.25 or more and 1.50 or less, 1.25 or more and 1.45 or less, 1.25 or more and 1.40 or less, 1.30 or more and 1.60 or less, 1.30 or more and 1.57 or less, 1.30 or more and 1.54 or less, 1.30 or more and 1.536 or less, 1.30 or more and 1.50 or less, 1.30 or more and 1.45 or less, 1.30 or more and 1.40 or less, 1.326 or more and 1.60 or less, 1.326 or more and 1.57 or less, 1.326 or more and 1.54 or less, 1.326 or more and 1.536 or less, 1.326 or more and 1.50 or less, 1.326 or more and 1.45 or less, and 1.326 or more and 1.40 or less.

The average value of δq/δa of the surface of the easily-adhesive layer as described above is the value in a given 10 μm×10 μm area.

The percentage of area with an average value of δq/δa of 1.60 or less with respect to the total area of the surface of the easily-adhesive layer is preferably 80% or more, more preferably 90% or more, further preferably 95% or more, even more preferably 98% or more, and most preferably 100%.

In a case where the easily-adhesive layer-including polyester film is in a sheet form, the number of areas with an average value of δq/δa of 1.60 or less among the ten 10 μm×10 μm areas specified in (1) through (4) below is preferably 8 or more, more preferably 9 or more, and further preferably 10. Among the above 10 areas, the number of areas where the coefficient of variation of δq/δa is 0.040 or less is preferably 8 or more, more preferably 9 or more, and further preferably 10.

(1) A circumscribed circle B1 that is circumscribed to sheet S is drawn.

(2) With the center of the circumscribed circle B1 as the center, an inscribed circle B2 that is inscribed to the sheet is drawn.

(3) With the center of the circumscribed circle B1 as the center, a circle B3 whose diameter is half the diameter of the inscribed circle B2 is drawn.

(4) On the circumference of circle B3, ten 10 μm×10 μm areas are selected at equal intervals. The signs C1 and C6 in FIG. 4 correspond to a part of the ten 10 μm×10 μm areas.

If the easily-adhesive layer-including polyester film is in a roll-like form, a sheet may be cut out from the roll to measure the average value of δq/δa and the coefficient of variation of δq/δa for the cut sheet. In addition, regarding the cut sheet, the number of areas with an average value of δq/δa of 1.60 or less among the ten 10 μm×10 μm areas specified in (1) through (4) above is preferably 8 or more, more preferably 9 or more, and further preferably 10. Among the above 10 areas, the number of areas where the coefficient of variation of δq/δa is 0.040 or less is preferably 8 or more, more preferably 9 or more, and further preferably 10.

The physical properties of the roll-shaped easily-adhesive layer-including polyester film are generally consistent in the flow direction. Thus, if a sheet cut from arbitrary position A in the width direction satisfies the average value of δq/δa in the present disclosure, the average value can be assumed to be satisfied at the arbitrary position A in the entire flow direction of the roll. The same applies to the coefficient of variation of δq/δa. To be sure, a sheet may be cut from two locations at arbitrary position A, one on the roll core side and the other on the roll surface side, and each cut sheet may be measured. Note that in the case of the roll core side, it is preferable to sample from an area away from the roll core. This is because areas close to the roll core may have defects such as winding habits. The area away from the roll core is preferably an area located 10 m or more and 20 m or less from the roll core when the polyester film has a thickness of 40 μm or more, and also preferably an area located more than 20 m and 40 m or less from the roll core when the polyester film has a thickness of less than 40 μm.

The physical properties of the roll-shaped easily-adhesive layer-including polyester film may be varied in the width direction. Thus, it is preferable to divide the roll into five equal parts in the width direction, cut a sheet from each of the five equal areas, and measure the average value of δq/δa for the cut sheets.

In the present disclosure, δa can be calculated by Equation 1 above. Equation 1 is adapted from the arithmetic mean height formula in ISO 25178-2:2012. In other words, the arithmetic mean height formula in ISO 25178-2:2012 uses the elevation as the data of Z-axis, while the Equation 1 uses the phase signal [deg], not the elevation, as the data of Z-axis. That is, the difference between δa and the arithmetic mean height in ISO 25178-2:2012 is that the former uses the phase signal [deg] as the data of Z-axis, while the latter uses the elevation [μm] as the data of Z-axis.

In the present disclosure, δq can be calculated by Equation 2 above. Equation 2 is adapted from the root-mean-square height formula in ISO 25178-2:2012. In other words, the root-mean-square height formula in ISO 25178-2:2012 uses the elevation as the data of Z-axis, while the Equation 2 uses the phase signal [deg], not the elevation, as the data of Z-axis. That is, the difference between δq and the root-mean-square height in ISO 25178-2:2012 is that the former uses the phase signal [deg] as the data of Z-axis, while the latter uses the elevation [μm] as the data of Z-axis.

The average value of δq/δa can be calculated by the following procedures A1 to A4.

(A1) A 10 μm×10 μm area of the surface of the easily-adhesive layer is measured using an atomic force microscope in a phase mode (when the product name “SPM-9600” manufactured by Shimadzu Corporation is used for measurement, the P-gain, I-gain, and offset are preferably adjusted).

(A2) Seven 2 μm×2 μm measurement evaluation regions are selected from within the 10 μm×10 μm measurement area.

(A3) δa, δq, and δq/δa are calculated for each of the seven measurement evaluation regions selected.

(A4) The average value of δq/δa is calculated based on the δq/δa of five locations, excluding the maximum and minimum values from δq/δa of the seven locations.

In A1 above, examples of the atomic force microscope include the product name “SPM-9600” manufactured by Shimadzu Corporation.

In A2 above, the 2 μm×2 μm regions to be selected should be selected from regions where the maximum height of the amplitude measured using the atomic force microscope is 90 nm or less. The maximum height is the maximum height Sz in ISO 25178-2:2012. By selecting the 2 μm×2 μm regions from the regions with Sz of 90 nm or less, the influence of foreign matter and defects can be easily eliminated. The seven measurement evaluation regions are selected preferably so as not to overlap one another, but they may overlap one another. Note that in the case where the measurement evaluation regions overlap, the percentage of overlap between any measurement evaluation region and the other six measurement evaluation regions is preferably 25% or less, more preferably 12% or less, and further preferably 5% or less, based on the area of the measurement evaluation region.

In A2 above, each 2 μm×2 μm measurement evaluation region is preferably selected from regions where the arithmetic mean height of the amplitude measured using the atomic force microscope is 10 nm or less in order to more easily eliminate the influence of foreign matter and defects. The arithmetic mean height is the arithmetic mean height δa in ISO 25178-2:2012.

The easily-adhesive layer preferably has a coefficient of variation of δq/δa of 0.040 or less as calculated based on the δq/δa of the five locations mentioned above.

By setting the coefficient of variation of δq/δa to 0.040 or less, the stress is more easily dispersed in the plane, so that the adhesion can be made better. The coefficient of variation of δq/δa is more preferably 0.039 or less, more preferably 0.037 or less, and more preferably 0.035 or less.

If the coefficient of variation of δq/δa is too small, it may be difficult for the components of the functional layer to soak into the easily-adhesive layer, and the adhesion between the easily-adhesive layer and the functional layer may be difficult to improve. Accordingly, the coefficient of variation of δq/δa is preferably 0.009 or more, more preferably 0.010 or more, more preferably 0.015 or more, and more preferably 0.018 or more.

Examples of an embodiment of the preferable range of δq/δa include 0.009 or more and 0.040 or less, 0.009 or more and 0.039 or less, 0.009 or more and 0.037 or less, 0.009 or more and 0.035 or less, 0.010 or more and 0.040 or less, 0.010 or more and 0.039 or less, 0.010 or more and 0.037 or less, 0.010 or more and 0.035 or less, 0.015 or more and 0.040 or less, 0.015 or more and 0.039 or less, 0.015 or more and 0.037 or less, 0.015 or more and 0.035 or less, 0.018 or more and 0.040 or less, 0.018 or more and 0.039 or less, 0.018 or more and 0.037 or less, and 0.018 or more and 0.035 or less.

The percentage of area with a coefficient of variation of δq/δa of 0.040 or less with respect to the total area of the surface of the easily-adhesive layer is preferably 80% or more, more preferably 90% or more, further preferably 95% or more, even more preferably 98% or more, and most preferably 100%.

The resin constituting the easily-adhesive layer is not particularly limited. Examples thereof include a thermoplastic resin such as polyester resin, polyurethane resin, and acrylic resin; and a thermosetting resin. Preferred is a thermoplastic resin. Among thermoplastic resins, preferred is any of polyester resin and polyurethane resin, which can easily reduce the refractive index difference between the polyester film and the easily-adhesive layer, and the refractive index difference between the easily-adhesive layer and an uneven layer. More preferred is a resin containing both polyester and polyurethane components.

The polyurethane component is likely to provide good adhesion but does not strengthen the coating film. Because of this, both polyester and polyurethane components are preferably contained. However, if the content of polyurethane component is too large compared to the polyester component, the average value of δq/δa and the coefficient of variation of δq/δa tend to increase due to easy phase separation. Since the polyurethane component is soft, too much polyurethane component tends to increase the average value of δq/δa and the coefficient of variation of δq/δa due to the difference of in-plane crosslink density. For this reason, in the resin containing both polyester and polyurethane components, the mass ratio between the polyester component and the polyurethane component is preferably 95:5 to 60:40, and more preferably 90:10 to 60:40.

The resin constituting the easily-adhesive layer has a number-average molecular weight of preferably 10,000 or more, and more preferably 15,000 or more. This resin has a number-average molecular weight of preferably 100,000 or less, and more preferably 60,000 or less. By setting the number-average molecular weight of the resin constituting the easily-adhesive layer to the above range, any cohesive fracture of the easily-adhesive layer can be easily suppressed.

The resin constituting the easily-adhesive layer has a glass transition temperature of preferably 30° C. or more, more preferably 50° C. or more, and further preferably 70° C. or more. This resin has a glass transition temperature of preferably 120° C. or less, more preferably 110° C. or less, and further more preferably 90° C. or less.

By setting the glass transition temperature of the resin constituting the easily-adhesive layer to 30° C. or more, heat during processing can cause the easily-adhesive layer to flow, thereby capable of easily suppressing generation of internal stress. Therefore, the average value of δq/δa and the coefficient of variation of δq/δa can be easily kept in the above range. Examples of the heat during processing include heat generated during the step of drying a coating liquid for the functional layer or heat generated by heating when laminating the optical laminate onto a polarizer.

By setting the glass transition temperature of the resin constituting the easily-adhesive layer to 120° C. or less, it is possible to easily suppress generation of stress due to the difference in thermal behavior between the easily-adhesive layer and the polyester film as caused by heat during processing. This makes it possible to suppress occurrence of, for instance, any crack in the easily-adhesive layer caused by the stress. Thus, by setting the glass transition temperature of the resin constituting the easily-adhesive layer to 120° C. or less, the average value of δq/δa and the coefficient of variation of δq/δa can be easily kept in the above range.

As long as the effects of the present disclosure are not impaired, the easily-adhesive layer may contain: an additive(s) such as a refractive index adjuster, a dye, a pigment, a leveling agent, a UV absorber, an antioxidant, and a light stabilizer; and/or a cross-linking agent to adjust hardness or viscosity. Examples of the cross-linking agent include a non-yellowing-type XDI-based, IPDI-based and HDI-based isocyanates, and an ionizing radiation-curable polyfunctional monomer.

The easily-adhesive layer may be formed by the in-line coating method, in which the coating is applied during the polyester film making process, or by the off-line coating method, in which the coating is applied after the polyester film making process.

In the in-line and off-line coating methods, it is preferable to use a coating liquid for the easily-adhesive layer, which liquid contains components constituting the easily-adhesive layer. For example, the easily-adhesive layer can be formed on a polyester film by applying the coating liquid for the easily-adhesive layer by a general-purpose coating method and drying. In this case, the drying time is preferably 120 seconds or less, and more preferably 90 seconds or less. By setting the drying time to 120 seconds or less, phase separation of the components constituting the easily-adhesive layer is suppressed and the average value of δq/δa and the coefficient of variation of δq/δa can be easily kept in the above range. If the drying time is too short, the surface of the coated film may become rough and the optical properties may deteriorate. For this reason, the drying time is preferably 15 seconds or more, and more preferably 20 seconds or more. The drying time can be adjusted in accordance with drying temperature and drying air speed.

The direction of the drying air is preferably opposite to the transfer direction of the polyester film. By adopting the above relationship between the direction of the drying air and the transfer direction of the polyester film, the time of drying the coating liquid for the easily-adhesive layer can be dramatically shortened without excessively increasing the drying temperature.

The temperature of drying the coating liquid for the easily-adhesive layer is preferably 50° C. or more and 200° C. or less, and more preferably 60° C. or more and 150° C. or less. By setting the drying temperature to 50° C. or more, the time of drying the coating liquid for the easily-adhesive layer can be shortened, so that the phase separation of the components constituting the easily-adhesive layer can be easily suppressed. By setting the drying temperature to 200° C. or less, thermal decomposition of the components constituting the easily-adhesive layer can be easily suppressed.

The coating liquid for the easily-adhesive layer preferably contains a solvent to enable dissolution or dispersion of the components constituting the easily-adhesive layer and to adjust the viscosity.

Examples of the solvent include ketones such as acetone, methyl ethyl ketone, methyl isobutyl ketone, and cyclohexanone; ethers such as dioxane and tetrahydrofuran; aliphatic hydrocarbons such as hexane; alicyclic hydrocarbons such as cyclohexane; aromatic hydrocarbons such as toluene, and xylene; carbon halides such as dichloromethane, and dichloroethane; esters such as methyl acetate, ethyl acetate, and butyl acetate; alcohols such as isopropanol, butanol, and cyclohexanol; cellosolves such as methylcellosolve and ethylcellosolve; glycol ethers such as propylene glycol monomethyl ether acetate; cellosolve acetates; sulfoxides such as dimethyl sulfoxide; and amides such as dimethylformamide and dimethylacetamide. Mixtures of these compounds may also be acceptable.

If the time of drying the solvent in the coating liquid for the easily-adhesive layer is too long, the components constituting the easily-adhesive layer are likely to be subject to phase separation. Thus, the solvent in the coating liquid for the easily-adhesive layer preferably contains a solvent with a fast evaporation rate.

On the other hand, if the time of drying the solvent in the coating liquid for the easily-adhesive layer is too short, the surface of the coated film tends to become rough. For this reason, the solvent in the coating liquid for the easily-adhesive layer is preferably used by mixing a solvent with an extremely fast evaporation rate and another solvent with a moderately fast evaporation rate.

As used herein, the solvent with an extremely fast evaporation rate means a solvent, the evaporation rate of which is 280 or more when the evaporation rate of butyl acetate is set to 100. As used herein, the solvent with a moderately fast evaporation rate means a solvent, the evaporation rate of which is 150 or more and less than 280 when the evaporation rate of butyl acetate is set to 100.

The solvent with an extremely fast evaporation rate has an evaporation rate of preferably 320 or more and 430 or less, and more preferably 340 or more and 400 or less. Examples of the solvent with an extremely fast evaporation rate include methyl ethyl ketone with an evaporation rate of 370 and normal heptane with an evaporation rate of 362.

The solvent with a moderately fast evaporation rate has an evaporation rate of preferably 170 or more and 250 or less, and more preferably 180 or more and 220 or less. Examples of the solvent with a moderately fast evaporation rate include toluene with an evaporation rate of 200 and propyl acetate with an evaporation rate of 214.

In the solvent in the coating liquid for the easily-adhesive layer, the mass ratio between the solvent with an extremely fast evaporation rate and the solvent with a moderately fast evaporation rate is preferably 50:50 to 90:10, and more preferably 70:30 to 85:15.

To easily suppress the phase separation, the lower limit of solid content concentration of the coating liquid for the easily-adhesive layer is preferably 2 mass % or more, and more preferably 4 mass % or more. Regarding the content of the solvent in the coating liquid for the easily-adhesive layer, the upper limit of the solid content concentration is preferably 30 mass % or less, and more preferably 10 mass % or less.

The dry coating amount of the easily-adhesive layer is preferably 0.05 g/m² or more and 0.75 g/m² or less. The thickness of the easily-adhesive layer is not particularly limited, and is preferably 10 nm or more and 600 nm or less, more preferably 20 nm or more and 300 nm or less, and further preferably 50 nm or more and 200 nm or less. In order to suppress interference fringes, the thickness of the easily-adhesive layer is preferably thin.

As used herein, the thicknesses of the easily-adhesive layer and the functional layer can be calculated by selecting 20 arbitrary locations on a cross-sectional photograph taken by scanning transmission electron microscopy (STEM) and averaging the values at the 20 locations. It is to be noted that the 20 locations should be selected without any bias of the place. The acceleration voltage and magnification of the STEM should be set according to the layer to be measured.

### <Size, Shape, Etc.>

The easily-adhesive layer-including polyester film may be in a sheet-like form cut to a predetermined size or in a roll-like form in which a long sheet is wound like a roll. The size of sheet is not particularly limited, but the maximum diameter is about 2 inches or more and 500 inches or less. The “maximum diameter” refers to the maximum length of the polyester film when any two points thereof are connected. For example, if the polyester film is rectangular, the diagonal of the rectangle is the maximum diameter. If the polyester film is circular, the diameter of the circle is the maximum diameter.

The width and length of the roll are not particularly limited, and generally the width is 500 mm or more and 8000 mm or less, and the length is about 100 m or more and 10000 m or less. The polyester film in a roll-like form can be cut into a sheet according to the size of image display device or the like. When cutting, it is preferable to exclude the edge of the roll where the physical properties are not stable.

The shape of sheet is not particularly limited, and may be, for instance, polygonal such as triangular, quadrangular, or pentagonal; or circular; or a random irregular shape. More specifically, if the polyester film is quadrangular, the aspect ratio is not particularly limited as long as there are no problems as a display screen. For example, width:height=1:1, 4:3, 16:10, 16:9, 2:1, 5:4, 11.8, etc.

### [Optical Laminate]

The optical laminate of the present disclosure has one or more functional layers on the easily-adhesive layer of the polyester film of the present disclosure described above.

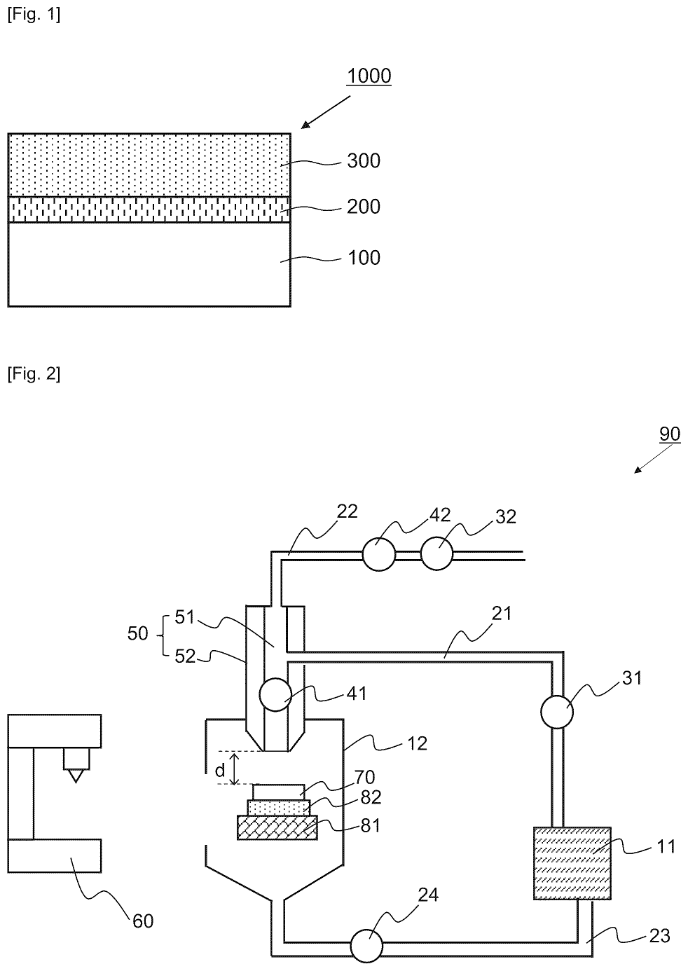

FIG. 1 is a cross-sectional view of an embodiment of an optical laminate 1000 of the present disclosure. The optical laminate 1000 shown in FIG. 1 has a polyester film 100, an easily-adhesive layer 200, and a functional layer 300 in this order.

### <Functional Layer>

The functional layer may be configured by a single layer or multiple layers. Examples of the layer constituting the functional layer include a hard coating layer, an anti-glare layer, an antireflective layer, a selective wavelength absorption layer, an antifouling layer, and an antistatic layer. The functional layer may have multiple functions in a single layer.

Among the functional layers, the antireflective layer includes a monolayer structure or a multi-layer structure. Examples of the single-layered antireflective layer include a monolayer of a low refractive index layer. Examples of the multi-layered antireflective layer include two layers having a high refractive index layer and a low refractive index layer, and further examples include a structure having three or more layers.

Examples of the functional layer to be formed on the easily-adhesive layer include B1 to B7 below.
B1: Monolayer configuration with a hard coating layer
B2: Monolayer configuration with an anti-glare layer
B3: Multilayer configuration with a hard coating layer and an antireflective layer in this order
B4: Multilayer configuration with an anti-glare layer and an antireflective layer in this order
B5: Multilayer configuration with a hard coating layer and an antifouling layer in this order
B6: Multilayer configuration with an anti-glare layer and an antifouling layer in this order
B7: Multilayer configuration with a hard coating layer, an antireflective layer, and an antifouling layer in this order

The functional layer in contact with the easily-adhesive layer among one or more functional layers preferably includes a cured product of an ionizing radiation curable resin composition. The functional layer in contact with the easily-adhesive layer is preferably a hard coating layer or an anti-glare layer.

When the functional layer in contact with the easily-adhesive layer includes a cured product of an ionizing radiation curable resin composition, the adhesion of the optical laminate tends to decrease. However, in the optical laminate of the present disclosure, the average value of δq/δa of the surface of the easily-adhesive layer is a given value. Thus, even if the functional layer in contact with the easily-adhesive layer includes a cured product of an ionizing radiation curable resin composition, the adhesion of the optical laminate can be easily improved.

In addition, if the functional layer in contact with the easily-adhesive layer includes a cured product of an ionizing radiation curable resin composition, the pencil hardness of the optical laminate can be easily made higher.

The functional layer in contact with the easily-adhesive layer among one or more functional layers preferably includes a cured product of an ionizing radiation curable resin composition and has a thickness of 0.5 μm or more. Such a configuration can facilitate a good pencil hardness of the optical laminate. The thickness of the functional layer in contact with the easily-adhesive layer is more preferably 1.0 μm or more and further preferably 2.0 μm or more, and the upper limit is preferably 20.0 μm or less, more preferably 10.0 μm or less, more preferably 7.0 μm or less, and more preferably 5.0 μm or less. The functional layer in contact with the easily-adhesive layer is preferably a hard coating layer or an anti-glare layer.

Examples of an embodiment of the preferable range of the thickness of the functional layer in contact with the easily-adhesive layer include 0.5 μm or more and 20.0 μm or less, 0.5 μm or more and 10.0 μm or less, 0.5 μm or more and 7.0 μm or less, 0.5 μm or more and 5.0 μm or less, 1.0 μm or more and 20.0 μm or less, 1.0 μm or more and 10.0 μm or less, 1.0 μm or more and 7.0 μm or less, 1.0 μm or more and 5.0 μm or less, 2.0 μm or more and 20.0 μm or less, 2.0 μm or more and 10.0 μm or less, 2.0 μm or more and 7.0 μm or less, and 2.0 μm or more and 5.0 μm or less.

The surface of the optical laminate on the functional layer side has a contact angle to pure water of preferably 80 degrees or more, more preferably 85 degrees or more, more preferably 90 degrees or more, more preferably 95 degrees or more, and more preferably 100 degrees or more. By setting the contact angle to 80 degrees or more, the optical laminate surface upon contact of another member becomes favorably slippery, and thus stress is unlikely to occur. Accordingly, the optical laminate can easily achieve favorable adhesion. In other words, by laminating a functional layer with an adjusted contact angle on the easily-adhesive layer of the easily-adhesive layer-including polyester film of the present disclosure with the average value of δq/δa within a given range, it is possible to more easily improve the adhesion of the optical laminate.

If the contact angle to pure water is too large, the functional layer located on the surface side of the optical laminate should contain a more amount of antifouling agent. This may result in a decrease in the physical properties such as the surface hardness of the optical laminate. Therefore, the contact angle is preferably 130 degrees or less, and more preferably 120 degrees or less. As used herein, the contact angle means a static contact angle measured by the θ/2 method.

The pure water used may be general-purpose pure water. The pure water generally has a specific resistance value of 0.1 MΩ·cm or more and 15 MΩ·cm or less.

Examples of an embodiment of the preferable range of the contact angle include 80 degrees or more and 130 degrees or less, 80 degrees or more and 120 degrees or less, 85 degrees or more and 130 degrees or less, 85 degrees or more and 120 degrees or less, 90 degrees or more and 130 degrees or less, 90 degrees or more and 120 degrees or less, 95 degrees or more and 130 degrees or less, 95 degrees or more and 120 degrees or less, 100 degrees or more and 130 degrees or less, and 100 degrees or more and 120 degrees or less.

The functional layer contains, for example, a binder resin and, if necessary, an additive(s).

The thickness of the functional layer may be selected, if appropriate, according to the function to be imparted.

The functional layer preferably includes, as the binder resin, a cured product of a curable resin composition. Examples of the cured product of the curable resin composition include a cured product of a thermosetting resin composition and a cured product of an ionizing radiation curable resin composition. In order to increase the pencil hardness, a cured product of an ionizing radiation curable resin composition is preferred.

The percentage of the cured product of a curable resin composition with respect to the total binder resin of the functional layer is preferably 60 mass % or more, more preferably 80 mass % or more, further preferably 90 mass % or more, and even more preferably 100 mass %.

The thermosetting resin composition is a composition that contains at least a thermosetting resin and is a resin composition cured by heating.

Examples of the thermosetting resin include acrylic resins, urethane resins, phenolic resins, urea melamine resins, epoxy resins, unsaturated polyester resins, and silicone resins. In the thermosetting resin composition, a curing agent is added to such a curable resin, as required.

The ionizing radiation curable resin composition is a composition containing a compound having an ionizing radiation curable functional group. As used herein, the term “compound having an ionizing radiation curable functional group” is sometimes referred to as an “ionizing radiation curable compound”.

The ionizing radiation means electromagnetic waves or charged particle beams with energy quanta allowing for polymerization or cross-linking of molecules. Usually, ultraviolet rays or electron beams are used. In addition, electromagnetic waves such as X-rays and γ-rays or charged particle beams such as α-rays and ion beams can also be used.

Examples of the ionizing radiation curable functional group include ethylenically unsaturated linking groups such as a (meth)acryloyl group, a vinyl group, and an allyl group, as well as an epoxy group and an oxetanyl group. The ionizing radiation curable compound is preferably a compound having an ethylenically unsaturated linking group, more preferably a compound having two or more ethylenically unsaturated linking groups, and among them, a polyfunctional (meth)acrylate compound having two or more ethylenically unsaturated linking groups is still more preferable.

As a polyfunctional (meth)acrylate compound, any monomer or oligomer may be used. However, an oligomer is preferably contained. In other words, the functional layer preferably includes a cured product of polyfunctional (meth)acrylate oligomer as a binder resin. In particular, the functional layer in contact with the easily-adhesive layer preferably includes a cured product of polyfunctional (meth)acrylate oligomer as a binder resin. The cured product of polyfunctional (meth)acrylate oligomer can suppress excessive curing shrinkage of the functional layer while providing favorable surface hardness of the optical laminate. This can facilitate favorable adhesion of the optical laminate while increasing the pencil hardness of the optical laminate.

In order to facilitate a better balance between the pencil hardness and adhesion of the optical laminate, it is more preferable to include an oligomer and a monomer as a polyfunctional (meth)acrylate compound. In other words, the functional layer preferably includes a cured product of polyfunctional (meth)acrylate oligomer and a cured product of polyfunctional (meth)acrylate monomer as a binder resin. In particular, the functional layer in contact with the easily-adhesive layer preferably includes a cured product of polyfunctional (meth)acrylate oligomer and a cured product of polyfunctional (meth)acrylate monomer as a binder resin.

In the case of using an oligomer and a monomer as a polyfunctional (meth)acrylate compound, the mass ratio between the oligomer and the monomer is preferably 5:95 to 95:5, more preferably 50:50 to 85:15, and further preferably 60:40 to 80:20.

Examples of the polyfunctional (meth)acrylate oligomer include a (meth)acrylate polymer such as urethane (meth)acrylate, epoxy (meth)acrylate, polyester (meth)acrylate, and polyether (meth)acrylate.

The urethane(meth)acrylate can be obtained, for example, by reaction of a polyhydric alcohol and an organic diisocyanate with hydroxy(meth)acrylate.

The lower limit of the weight-average molecular weight of the polyfunctional (meth)acrylate oligomer is preferably 500 or more and more preferably 1000 or more, and the upper limit is preferably 5000 or less and more preferably 3000 or less.

By setting the weight-average molecular weight of the oligomer to 500 or more, excessive curing shrinkage of the functional layer can be easily suppressed. In addition, by setting the weight-average molecular weight of the oligomer to 5000 or less, the decrease in pencil hardness can be easily suppressed.

Examples of an embodiment of the weight-average molecular weight range of the polyfunctional (meth)acrylate oligomer include 500 or more and 5000 or less, 500 or more and 3000 or less, 1000 or more and 5000 or less, and 1000 or more and 3000 or less.

As used herein, the weight-average molecular weight and the number-average molecular weight mean values in terms of polystyrene as measured by gel permeation chromatography.

Among the polyfunctional (meth)acrylate compounds, examples of a bifunctional (meth)acrylate monomer include ethylene glycol di(meth)acrylate, bisphenol A tetraethoxydiacrylate, bisphenol A tetrapropoxydiacrylate, and 1,6-hexanediol diacrylate.

Examples of a trifunctional or more (meth)acrylate monomer include trimethylolpropane tri(meth)acrylate, pentaerythritol tri(meth)acrylate, pentaerythritol tetra(meth)acrylate, dipentaerythritol hexa(meth)acrylate, dipentaerythritol tetra(meth)acrylate, and isocyanurate-modified tri(meth)acrylate.

The above (meth)acrylate monomer may be partially modified in the molecular skeleton. It may also be possible to use, for example, a (meth)acrylate monomer modified with, for instance, ethylene oxide, propylene oxide, caprolactone, isocyanurate, alkyl, cyclic alkyl, aromatic, or bisphenol.

To adjust the viscosity of the coating liquid for the functional layer, for example, a monofunctional (meth)acrylate may be added as an ionizing radiation curable compound.

Examples of the monofunctional (meth)acrylate include methyl (meth)acrylate, ethyl (meth)acrylate, propyl (meth)acrylate, butyl (meth)acrylate, pentyl (meth)acrylate, hexyl (meth)acrylate, cyclohexyl (meth)acrylate, 2-ethylhexyl (meth)acrylate, lauryl (meth)acrylate, stearyl (meth)acrylate, and isobornyl (meth)acrylate.

One of the ionizing radiation curable compound may be used alone or two or more thereof may be used in combination.

In addition to the ionizing radiation curable compound, a polymer may be added to the coating liquid for the functional layer to adjust the viscosity. Examples of the polymer include those having a weight-average molecular weight of more than 5,000 and 200,000 or less.

When the ionizing radiation curable compound is a UV curable compound, the ionizing radiation curable resin composition preferably contains an additive(s) such as a photopolymerization initiator and a photopolymerization-promoting agent.

Examples of the photopolymerization initiator include at least one selected from the group consisting of acetophenone, benzophenone, α-hydroxyalkylphenone, Michler ketone, benzoin, benzyl dimethyl ketal, benzoyl benzoate, an α-acyl oxime ester, anthraquinone, halogenoketone, and a thioxanthone compound. Among these, α-hydroxyalkylphenone, which does not yellow easily, is preferred.

The photopolymerization-promoting agent can reduce the inhibition of polymerization by air during curing and accelerate the curing speed. Examples thereof include at least one selected from the group consisting of a p-dimethylaminobenzoic acid isoamyl ester and a p-dimethylaminobenzoic acid ethyl ester.

The functional layer may optionally contain an additive(s).

The additive(s) may be selected from general-purpose materials, as appropriate, according to the function to be imparted to the functional layer. For example, in the case of imparting an anti-glare property to the functional layer, it is preferable to include organic and/or inorganic particles as an additive. In the case of imparting an antireflective property to the functional layer, it is preferable to include a refractive index adjusting material such as a high refractive index material or a low refractive index material as an additive. In the case of imparting an antifouling property to the functional layer, it is preferable to include an antifouling agent as an additive.

Further, examples of the additive include an antistatic agent, a leveling agent, a UV absorber, a dye, a pigment, conductive particles, a flocculant, an antifoamer, an antioxidant, and a light stabilizer.

### <Physical Properties>

The optical laminate has a JIS K7361-1:1997 total light transmittance of preferably 50% or more, more preferably 80% or more, and further preferably 90% or more.

The total light transmittance and haze described below are measured while the light incident surface is on the polyester film side. The total light transmittance and haze described below can be measured, for example, with a haze meter (model number: HM-150) manufactured by MURAKAMI COLOR RESEARCH LABORATORY CO., LTD.

The lower limit of the haze according to JIS K7136:2000 of the optical laminate is preferably 0.3% or more, more preferably 0.4% or more, and further preferably 0.5% or more and the upper limit is preferably 10% or less, more preferably 7% or less, and further preferably 5% or less.

### <Size, Shape, Etc.>

The optical laminate may be a sheet-like form cut to a predetermined size or in a roll-like form in which a long sheet is wound like a roll. The size of the sheet is not particularly limited, but the maximum diameter is about 2 inch or more and 500 inch or less. The “maximum diameter” refers to the maximum length of the optical laminate when any two points thereof are connected. For example, in the case where the optical laminate is rectangular, the rectangular diagonal line is the maximum diameter. If the optical laminate is circular, the diameter of the circle is the maximum diameter.

The width and the length of the roll is not particularly limited, and in general, the width is 500 mm or more and 8000 mm or less, and the length is about 100 m or more and 10000 m or less. The optical laminate in a roll-like form can be cut into a sheet according to the size of an image display device or the like for use. When cutting, it is preferable to exclude the edge of the roll where the physical properties are not stable.

The shape of sheet is not particularly limited, and may be, for instance, polygonal such as triangular, quadrangular, or pentagonal; or circular; or a random irregular shape. More specifically, if the optical laminate is quadrangular, the aspect ratio is not particularly limited as long as there are no problems as a display screen. For example, width:height=1:1, 4:3, 16:10, 16:9, 2:1, 5:4, 11:8, etc.

### [Polarizing Plate]

A polarizing plate of the present disclosure includes: a polarizer; a first transparent protective plate disposed on one side of the polarizer; and a second transparent protective plate disposed on the other side of the polarizer, wherein at least one of the first transparent protective plate or the second transparent protective plate is the optical laminate of the present disclosure as described above, and wherein the optical laminate is arranged so that a surface on the functional layer side faces a side opposite to the polarizer.

### <Polarizer>

Examples of the polarizer include a sheet-type polarizer such as a polyvinyl alcohol film, a polyvinyl formal film, a polyvinyl acetal film, and an ethylene-vinyl acetate copolymer-based saponified film, dyed with iodine or the like and stretched; a wire grid-type polarizer composed of many metal wires arranged in parallel; a coated polarizer coated with a lyotropic liquid crystal or dichroic guest-host material; and a multilayer thin-film polarizer. These polarizers may be reflective polarizers with a function of reflecting a non-transmittable polarization component.

### <Transparent Protective Plate>

The first transparent protective plate is placed on one side of the polarizer, and the second transparent protective plate is placed on the other side. At least one of the first transparent protective plate or the second transparent protective plate is the optical laminate of the present disclosure as described above.

Examples of the first transparent protective plate and the second transparent protective plate other than the optical laminate include a plastic film and glass. Examples of the plastic film include a polyester film, a polycarbonate film, a cycloolefin polymer film, and an acrylic film. To provide favorable mechanical strength, a stretched film thereof is preferable. Examples of the glass include alkali glass, nitride glass, soda lime glass, borosilicate glass, and lead glass. In addition, the glass as a polarizer-protecting transparent protective plate preferably serves as other components of the image display device as well. For example, the glass substrate of the liquid crystal display element preferably also serves as the polarizer-protecting transparent protective plate.

The polarizer and the transparent protective plate are preferably bonded together via an adhesive. The adhesive used may be a general-purpose adhesive and preferably is a PVA-based adhesive.

Regarding the polarizing plate of the present disclosure, both the first transparent protective plate and the second transparent protective plate may be the optical laminates of the present disclosure as described above. However, one of the first transparent protective plate or the second transparent protective plate is preferably the optical laminate of the present disclosure as described above. In addition, in the case where the polarizing plate of the present disclosure is used as a polarizing plate disposed on the light emitting side of a display element, the transparent protective plate on the light-emitting surface side of the polarizer is preferably the optical laminate of the present disclosure as described above. On the other hand, in the case where the polarizing plate of the present disclosure is used as a polarizing plate disposed on a side opposite to the light-emitting surface side of a display element, the transparent protective plate on a side opposite to the light-emitting surface side of the polarizer is preferably the optical laminate of the present disclosure as described above.

### [Surface Plate]

The surface plate of the present disclosure is a surface plate including an optical laminate laminated on a resin plate or a glass plate, wherein the optical laminate is the optical laminate of the present disclosure as described above, and wherein the optical laminate is arranged so that a surface on the functional layer side faces a side opposite to the resin plate or the glass plate.

The surface plate of the present disclosure may be used, for example, as a surface plate for an image display device. In addition, the surface plate of the present disclosure may also be used as a surface plate for protecting an article such as a watch or painting. Further, the surface plate of the present disclosure may be used as a component for a show window and showcase.

The surface plate for an image display device is preferably arranged so that the side to which the optical laminate is bonded faces the surface side. In other words, the surface plate for an image display device is preferably arranged so that the side to which the optical laminate is bonded faces a side opposite to the display element.

The surface plate for protecting an article is preferably arranged so that the side to which the optical laminate is bonded faces a side opposite to the article.

The resin or glass plate used may be a resin or glass plate that is commonly used as a surface plate.

To provide favorable strength, the thickness of the resin or glass plate is preferably 10 μm or more. The upper limit of the thickness of the resin or glass plate is usually 5000 μm or less, but since thinner image display devices are preferred in recent years, the upper limit is preferably 1000 μm or less, more preferably 500 μm or less, and still more preferably 100 μm or less.

Examples of an embodiment of the range of thickness of the resin or glass plate include 10 μm or more and 5000 μm or less, 10 μm or more and 1000 μm or less, 10 μm or more and 500 μm or less, and 10 μm or more and 100 μm or less.

### [Image Display Panel]

The image display panel of the present disclosure includes the optical laminate of the present disclosure as described above arranged on a display element.

In the image display panel, the optical laminate is preferably arranged so that a surface on the functional layer side faces a side opposite to the display element. In addition, the optical laminate is preferably arranged on the topmost surface of the image display panel.

Examples of the display element include a liquid crystal display element, an EL display element such as an organic EL display element or an inorganic EL display element, or a plasma display element. Further examples thereof include an LED display element such as a mini-LED display element or a micro-LED display element. Another example thereof is a laser hologram display element. These display elements may have a touch panel function inside the display element.

Examples of the display system for the liquid crystal of the liquid crystal display element include an IPS, VA, multi-domain, OCB, STN, TSTN, and ferroelectric liquid crystal systems. If the display element is a liquid crystal display element, a backlight is necessary. The backlight is disposed on the side of the liquid crystal display element opposite to the side having the optical laminate. Examples of the backlight include a backlight using quantum dots and a backlight using white light-emitting diodes.

The image display panel may be a foldable image display panel or a rollable image display panel. In addition, the image display panel may be an image display panel with a touch panel.

The size of the image display panel is not particularly limited, but the maximum diameter is from about 2 inches to 500 inches. The maximum diameter means the maximum length of the image display panel when any two points in the surface are connected.

### [Image Display Device]

The image display device of the present disclosure includes the image display panel of the present disclosure as described above.

In the image display device, the optical laminate is preferably arranged so that a surface on the functional layer side faces a side opposite to the display element. In addition, the optical laminate is preferably arranged on the topmost surface of the image display device.

The image display device of the present disclosure is preferably further provided with a drive control unit electrically connected to the image display panel, and a housing that accommodates, for example, the image display panel and the drive control unit.

If the display element is a liquid crystal display element, a backlight is necessary in the image display device of the present disclosure. The backlight is disposed on a side opposite to the light-emitting surface side of the liquid crystal display element.

The size of image display device is not particularly limited, but the maximum diameter of the effective display area is from about 2 inches or more and 500 inches or less.

The effective display area of an image display device is an area in which an image can be displayed. For example, if the image display device has a housing that surrounds the display element, the area inside the housing is the effective display area.

The maximum diameter of the effective display area refers to the maximum length of the effective display area when any two points therein are connected. For example, if the effective display area is rectangular, the diagonal of the rectangle is the maximum diameter. If the effective display area is circular, the diameter of the circle is the maximum diameter.

### EXAMPLES

Hereinafter, the present disclosure will be described specifically with reference to Examples and Comparative Examples. The present disclosure is not limited to embodiments described in the Examples.

### 1. Evaluation, Measurement

The following measurements and evaluations were conducted on the easily-adhesive layer-including polyester films and optical laminates obtained in Examples and Comparative Examples. The results are shown in Table 1 or 2. Note that unless otherwise indicated, the atmosphere for each measurement and evaluation was set at a temperature of 23±5° C. and a relative humidity of 40% or more and 65% or less. Samples used for measurement and evaluation were free from defects, clean and flat. In addition, unless otherwise noted, samples of interest were exposed to the above atmosphere for 30 minutes or more and 60 minutes or less before each measurement and evaluation.

### 1-1. Pencil Hardness

Regarding the easily-adhesive layer-including polyester films of the Examples and Comparative Examples, the pencil hardness of each polyester film was measured. The method of measuring a pencil hardness was according to the procedures (1) to (6) in the text of specification. The pencil hardness was measured before formation of the easily-adhesive layer. For commercially available polyester films with easily-adhesive formed on one side, the pencil hardness of the side without the easily-adhesive layer was measured. The pencil hardness was measured for both the slow axis and the fast axis.

1-2. Calculation of Average Value of δq/δa

Samples of 5 mm×5 mm were cut from the easily-adhesive layer-including polyester films of the Examples and Comparative Examples. Next, a 10 μm×10 μm area of the surface of the adhesive layer in each sample was measured using an atomic force microscope in a phase mode. The measuring device and measurement conditions are as follows. Seven 2 μm×2 μm measurement evaluation regions were selected from within the 10 μm×10 μm measurement area. The above seven regions were selected from the regions where the maximum height of amplitude is 90 nm or less and the arithmetic mean height of amplitude is 10 nm or less, as measured using atomic force microscope. δa, δq, and δq/δa were calculated for each of the seven measurement evaluation regions. The average value of δq/δa and the coefficient of variation of δq/δa were calculated based on the δa and δq of the five measurement evaluation regions, excluding the maximum and minimum values from δq/δa of the seven measurement evaluation regions. Note that in the following measuring device, δa and δq of the selected measurement evaluation region are automatically displayed when the 2 μm×2 μm measurement evaluation region is selected on the screen (provided that due to the following measuring device setting, the items corresponding to δa are displayed as “Ra” and the items corresponding to δq are displayed as “Rq” on the display screen of the following measuring device).

### <Measuring Device>

“SPM-9600”, product name of Shimadzu Corporation

### <Analysis Software>

SPM Manager

### <AFM Analysis Conditions>

Tilt compensation: line fitting

### <Cantilever Used>

Model number “NCHR” by NanoWorld, Inc.
(Resonance frequency: 320 kHz, Spring constant: 42 N/m)

### <Measurement Mode>

Phase (In the “phase mode” of the above measuring device, not only phase but also amplitude is measured)

### <Measurement Conditions>

### —Amplitude⋅Phase—

Sensitivity: ×2
Phase offset: 95.00 deg

### —XY Control—

Scanning range: 10.0000 μm
Scanning speed: 1.00 Hz
Number of pixels: 512×512
Offset X: 0.0000 μm
Offset Y: 0.0000 μm
Scanning angle: 0.0000 deg

### —Z Control—

Operating point: 0.228 V
P gain: 0.001
I Gain: 15000.000
Offset Z: 0.0630 μm

### 1-3. Adhesion

A cutter blade was inserted from the hard coating layer side of the optical laminate in each of the Examples or Comparative Examples to form a 100-square grid of cuts (the number of cuts: 11 vertical and horizontal cut lines; cut spacing: 1 mm). The cutter blade used was a NT's product number “BA-52P.” Next, an adhesive tape (NICHIBAN Co., Ltd.; product name “Cellotape (registered trademark)”) was applied onto the surface of the optical laminate with a grid pattern formed, and then the adhesive tape was peeled off. In this way the peeling test was conducted in accordance with the cross-cut method specified in JIS K5600-5-6:1999. The adhesion of the optical laminate of each of the Examples or Comparative Examples was evaluated with the following evaluation criteria.

<Evaluation criteria>

A: The number of detached squares is 0, and no squares are partially missing.

B: The number of detached squares is 0, but some of the squares are missing, for example, part of a square is missing along the cut.

C: The number of detached squares is 1 or more.

### 1-4. Total Light Transmittance (Tt) and Haze (Hz)

Total light transmittance according to JIS K7361-1:1997 and haze according to JIS K7136:2000 for the optical laminate of each of the Examples or Comparative Examples were measured with a haze meter (HM-150, manufactured by MURAKAMI COLOR RESEARCH LABORATORY CO., LTD.). The light-incident surface was on the polyester film side.

### 1-5. Measurement of Erosion Rate

The erosion rates of polyester films for the easily-adhesive layer-including polyester films of the Examples and Comparative Examples were measured with a device for measuring erosion rate (MSE tester, model number “MSE-A203” of Palmeso Co., Ltd.; cross-sectional shape of the nozzle: 1 mm×1 mm square; means for measuring a cross-sectional profile: stylus type) to calculate each E₀₋₂₀ and σ₀₋₂₀/E₀₋₂₀. Measurement was performed for each polyester film in triplicate, and the average of the three measurements was defined as E₀₋₂₀ and σ₀₋₂₀/E₀₋₂₀ for each polyester film. The erosion rate measurement area is 1 mm×1 mm. Measurement of the erosion rate was performed before the formation of the easily-adhesive layer. For commercially available polyester films with easily-adhesive formed on one side, the pencil hardness of the side without the easily-adhesive layer was measured.

The erosion rate of each sample was measured after the following calibration using a standard acrylic plate. In addition, each test solution was prepared before the calibration, and a preliminary distributed operation was conducted before the calibration. Here, the above standard acrylic plate gave an AcE (average of erosion rates of acrylic plate as measured under the measurement condition A), as described in the text of specification, within the range of 1.786 μm/g or more and 1.974 μm/g or less.

### (0-1) Preparation of Test Solution

The test solution was prepared by mixing pure water, a dispersing agent (product name “DEMOL N” of Wako Pure Chemical Industries, Ltd.), and spherical silica (model number “MSE-BS-5-3” designated by Palmeso Co., Ltd.; full width at half maximum of particle size distribution: 4.2 μm) with an average particle size (median diameter) of 3.94 μm at the mass ratio of 968:2:30 in a beaker, and mixed with a glass rod. The prepared test solution and a stirring bar were placed in a container (pot), and the pot was then covered with a lid and a clamp was attached. Next, the pot was put into the measuring device. In the Examples, as the model number “MSE-BS-5-3” designated by Palmeso Co., Ltd., the product number “BS5-3” of Potters-Ballotini Co., Ltd. was used.

### (0-2) Distributed Operation

The pot containing the test solution was put into the measuring device, and a dummy sample was then set on the sample mount. Next, the buttons “Erosion force setting” and “Perform” on the control panel of the main unit of the measuring device were pressed in this order. Then, the prescribed values were entered as the flow rates of the test solution and compressed air, the pressure of compressed air, and the pressure of the test solution in the nozzle, and the test solution was jetted onto the dummy sample. After the jetting was stopped, the buttons “Return”, “Completed”, and “Confirm” on the control panel were pressed in this order.

### (1) Calibration

An acrylic plate with a thickness of 4 mm, which was a calibration sample, was fixed to the sample mount of the measuring device via a double-sided tape (“Kapton double-stick tape”, product number: P-223 1-6299-01 of Nitto Denko America). The acrylic plate is a PMMA plate.

Next, the sample mount having the acrylic plate fixed was set on the measuring device.

Next, a micro gauge was unlocked and the height of the sample mount was adjusted with a height gauge. The distance between the jetting hole of the measuring device and the acrylic plate was adjusted to 4 mm.

Next, the button “To the processing condition input screen” on the control panel of the main unit of the measuring device was pressed, and the “Number of steps: 1, Specified amount jetted g×1 time” was then set. The amount jetted was set to 4 g.

Next, the buttons “Setting completed”, “Start operation”, and “Yes” of the control panel were pressed in this order. The flow rates of the test solution and compressed air, the pressure of compressed air, and the pressure of the test solution in the nozzle were maintained at the values entered in “(0-2) Distributed operation”.

Next, the “Online” button on the control screen of the data processing PC was clicked to turn off the online mode and change to the offline mode.

Next, the “Descend” button on the control screen was clicked to move downward the stylus of the stylus-type step profiler in the cross-sectional profile acquisition unit.

Next, the micro gauge was confirmed to be unlocked, and the micro gauge was then turned toward the upward direction. At that time, the red arrow on the monitor was adjusted to be at the middle level. The above adjustment enables the stylus of the stylus-type step profiler to be in contact with the surface of the calibration sample, so that the zero point of the z axis, namely the height direction, can be adjusted.

Next, the micro gauge was switched from the unlocked (off) to on state.

Next, the “Ascend” button was clicked to move upward the stylus of the stylus-type step profiler in the cross-sectional profile acquisition unit.

Next, the “Offline” button on the control screen of the data processing PC was clicked to turn off the offline mode and change to the online mode.

Next, the cover of the main unit of the measuring device was closed, the button “Confirm” on the control panel of the main unit of the measuring device was pressed, and 4 g of the test solution was jetted.

The jetting of the test solution was stopped, “Perform” was then clicked, and the erosion rate was calculated. When the erosion rate was within the range of ±5% of 1.88 (μm/g) as a reference, the calibration was ended. When the erosion rate was deviated from the above range, the flow rate of the test solution, the flow rate of compressed air, the pressure of compressed air, and the pressure of the test solution in the nozzle were adjusted. In this way, the calibration was repeated until the erosion rate reached the above range.

### (2) Measurement of Erosion Rate of Each Sample

### (2-1) Mounting of Sample

Each sample (plastic film in the Examples or Comparative Examples) was laminated onto a stainless steel plate to make a laminate. The laminate was fixed to the sample mount via a double-sided tape (“Kapton double-stick tape”, product number: P-223 1-6299-01 of Nitto Denko America). The sample was 1 cm×1 cm in size.

Next, the sample mount was set on the measuring device. Next, a micro gauge was unlocked and the height of the sample mount was adjusted with a height gauge. The distance between the jetting hole of the measuring device and the plastic film was adjusted to 4 mm.

Next, the button “To the processing condition input screen” on the control panel of the main unit of the measuring device was pressed. After that, the number of steps was entered, and the amount of the test solution jetted (g/jetting) was entered for each step. The amount jetted per step was in the range of 0.5 g or more and 3.0 g or less. The flow rates of the test solution and compressed air, the pressure of compressed air, and the pressure of the test solution in the nozzle were maintained at the conditions that had passed in the “(1) Calibration”.

Next, the buttons “Setting completed”, “Start operation”, and “Yes” of the control panel were pressed in this order.

Next, the “Online” button on the control screen of the data processing PC was clicked to turn off the online mode and change to the offline mode.

Next, the “Descend” button on the control screen was clicked to move downward the stylus of the stylus-type step profiler in the cross-sectional profile acquisition unit.

Next, the micro gauge was confirmed to be unlocked, and the micro gauge was then turned toward the upward direction. At that time, the red arrow on the monitor was adjusted to be at the middle level. The above adjustment enables the stylus of the stylus-type step profiler to be in contact with the surface of the calibration sample, so that the zero point of the z axis, namely the height direction, can be adjusted.

Next, the micro gauge was switched from the unlocked (off) to on state.

Next, the “Ascend” button was clicked to move upward the stylus of the stylus-type step profiler in the cross-sectional profile acquisition unit.

Next, the “Offline” button on the control screen of the data processing PC was clicked to turn off the offline mode and change to the online mode.

### (2-2) Start of Measurement

The cover of the main unit of the measuring device was closed. The button “Confirm” on the control panel of the main unit of the measuring device was pressed. While one cycle consisted of jetting of the test solution and measurement of the cross-sectional profile, the cycle was repeated until the depth of the cross-sectional profile exceeded 20 μm. Specifically, the cycle was repeated until the depth of the cross-sectional profile reached the depth of 25 μm or more and 30 μm or less.

After the measurement, the attached software “MseCalc” was started and “Analysis method” was clicked. Next, “Average value analysis” was clicked. Next, the “Add” button on the average value analysis screen was clicked twice. Then, “A-1” and “A-2” were displayed in the section of analysis name. The “Criteria” section of “A-1” was double-clicked to display “◯” in the criteria section.

Next, the “A-1” on the average value analysis screen was clicked to activate it, and the position of the X-axis position bar was controlled. The position of the position bar was determined at the location where the plastic film was not worn in the cross-sectional profile screen.

Next, the A-2 on the average value analysis screen was clicked to activate it, and the position of the X-axis position bar was controlled. The position of the position bar was determined at the deepest point where the plastic film was worn in the cross-sectional profile screen.

Next, the “File List” of the attached software was clicked. Next, “BS5-3” was selected in the “Correction” section of the file list screen.

Next, the cross-sectional profile and erosion rate data for each step were output in csv format, and the erosion rate E₀₋₂₀ was calculated. Specifically, the “erosion rates (corrected)” of the csv output data, the depth of which was 0 μm or more and 20 μm or less were averaged to calculate the erosion rate E₀₋₂₀.

### 1-6. Rainbow Unevenness

Rainbow unevenness of the easily-adhesive layer-including polyester film of each of the Examples or Comparative Examples was evaluated by the following procedures (1) to (3).

(1) Samples were cut and prepared into a A4 size from the easily-adhesive layer-including polyester films of the Examples and Comparative Examples.

(2) Each sample prepared in (1) was adhered via water to the polarizing plate on the viewing side of an image display device with the following configuration. The water present at the interface between the polarizing plate on the viewing side and the sample can suppress the optical effects of the surface irregularities of the polarizer protection film of the polarizing plate on the viewing side. The longitudinal direction of the sample and the direction of the absorption axis of the polarizer in the polarizing plate on the viewing side were arranged at a given angle range. The given angle range were 0±5 degrees, 45±5 degrees, and 90±5 degrees. The direction of the absorption axis of the polarizer in the polarizing plate on the viewing side can be checked as follows.

### <How to Check Direction of Absorption Axis of Polarizer in Polarizing Plate on the Viewing Side>

A polarizing film with the direction of the absorption axis marked is superimposed on an image display device having the following configuration. The polarizing film is slowly rotated and stopped at the position where it becomes black. At the position, the direction orthogonal to the marking of the polarizing film is the direction of the absorption axis of the polarizer in the polarizing plate on the viewing side.

(3) The image display device was turned on in a dark room environment, and 10 evaluators observed the device from various angles with the naked eyes and evaluated the presence or absence of rainbow unevenness according to the criteria below. The distance between the observer and the image display device was from 0.3 to 1.0 m. The image display system was turned on under the following conditions: color temperature of 6500 K, white display, and luminance of 250 cd/m².

### <Configuration of Image Display Device>

Backlight light source: White LED
Polarizing plate on the light source side: Having TAC films as protective films on both sides of the polarizer made of PVA and iodine. The polarizing plate polarizer is positioned so that the direction of the absorption axis of the polarizer is perpendicular to the horizontal direction of the screen.
Image display cell: Liquid crystal cell
Polarizing plate on the viewing side: Polarizing plate in which TAC films are used as polarizer protection films on both sides of the polarizer made of PVA and iodine. The polarizing plate is positioned so that the direction of the absorption axis of the polarizer is perpendicular to the direction parallel to the screen. An anti-glare layer is laminated on the polarizer protection film on the viewing side.
Size: 20 inches diagonal

### <Evaluation Criteria>

AA: 7 or more and 10 or less observers answered that rainbow unevenness was not visible in any of the three angle ranges.

A: 6 observers answered that rainbow unevenness was not visible in any of the three angle ranges.

B: 5 observers answered that rainbow unevenness was not visible in any of the three angle ranges.

B: 2 or more and 4 or less observers answered that rainbow unevenness was not visible in any of the three angle ranges.

C: 1 or less observers answered that rainbow unevenness was not visible in any of the three angle ranges.

### 2. Preparation of Coating Liquid for Easily-Adhesive Layer

### 2-1. Coating Liquid A for Easily-Adhesive Layer

The following materials were mixed and subjected to an ester exchange reaction at 200° C. for 2 hours to produce a compound 1.
Dimethyl terephthalate 106 parts by mass
Ethylene glycol 25 parts by mass
1,4-Butanediol 25 parts by mass
Zinc acetate 0.1 parts by mass
Antimony trioxide 0.1 parts by mass

Next, to the compound 1, 4.0 parts by mass of fumaric acid were added, and the esterification reaction was carried out at 230° C. for 2 hours. The polycondensation reaction was then carried out under reduced pressure (3 to 6 mmHg) at 250° C. for 1 hour to produce a compound 2.

To the compound 2 was added 230 parts by mass of methyl ethyl ketone and 120 parts by mass of isopropyl alcohol. The mixture was stirred while heating at 70° C. to dissolve the compound 2 to thereby obtain a resin solution 3.

To the resin solution 3 was added 25 parts by mass of m-xylene diisocyanate, and stirred for 3 hours. The temperature of the reaction vessel was then raised to 100° C. to remove methyl ethyl ketone and isopropyl alcohol to thereby obtain resin 4 for easy adhesion.

The resin 4 for easy adhesion was dissolved in a mixed solvent obtained by mixing of methyl ethyl ketone and toluene at a mass ratio of 8:2 to obtain coating liquid A for the easily-adhesive layer with a solid content of 5 mass %. The mass ratio between the polyester component and the polyurethane component of the resin in the coating liquid A for the easily-adhesive layer is 8:2.

### 2-2. Coating Liquid B for Easily-Adhesive Layer

The following materials were mixed and subjected to an ester exchange reaction at 200° C. for 2 hours to produce a compound 5.
Dimethyl terephthalate 106 parts by mass
Ethylene glycol 28 parts by mass
1,4-Butanediol 30 parts by mass
Zinc acetate 0.1 parts by mass
Antimony trioxide 0.1 parts by mass

Next, to the compound 5, 4.0 parts by mass of fumaric acid were added, and the esterification reaction was carried out at 230° C. for 2 hours. The polycondensation reaction was then carried out under reduced pressure (3 to 6 mmHg) at 250° C. for 1 hour to produce a compound 6.

To the compound 6 was added 230 parts by mass of methyl ethyl ketone and 120 parts by mass of isopropyl alcohol. The mixture was stirred while heating at 70° C. to dissolve the compound 6 to thereby obtain a resin solution 7.

To the resin solution 7 was added 45 parts by mass of m-xylene diisocyanate, and stirred for 3 hours. The temperature of the reaction vessel was then raised to 100° C. to remove methyl ethyl ketone and isopropyl alcohol to thereby obtain resin 8 for easy adhesion.

The resin 8 for easy adhesion was dissolved in a mixed solvent obtained by mixing of methyl ethyl ketone and toluene at a mass ratio of 8:2 to obtain coating liquid B for the easily-adhesive layer with a solid content of 5 mass %. The mass ratio between the polyester component and the polyurethane component of the resin in the coating liquid B for the easily-adhesive layer is 7:3.

### 2-3. Coating Liquid C for Easily-Adhesive Layer

The following materials were mixed to prepare coating liquid C for the easily-adhesive layer.
First urethane-based resin 12 parts by mass

(Dainippon Ink and Chemicals; product name: HYDRAN AP-20; glass transition temperature: 27° C.; flow start temperature: 90° C.)
Second urethane-based resin 3 parts by mass

(Dainippon Ink and Chemicals; product name: HYDRAN AP-30; glass transition temperature: 61° C.; flow start temperature: 105° C.)
Curing agent 2 parts by mass

(Sumitomo Chemical, Co., Ltd.; product name: Sumimar M30W; main component: methylolated melamine)
Water 85 parts by mass

### 2-4. Coating Liquid D for Easily-Adhesive Layer

The following materials were mixed and subjected to an ester exchange reaction at 160-220° C. using a routine procedure to produce a compound 9.
Dimethyl terephthalate 34.5 parts by mass
1,4-Butanediol 21.1 parts by mass
Ethylene glycol 27 parts by mass
Tetra-n-butyl titanate 0.05 parts by mass

Next, to the compound 9, 1.4 parts by mass of fumaric acid and 16 parts by mass of sebacic acid were added, and an esterification reaction was carried out at 200 to 220° C. to obtain copolymerized polyester resin 10.

To a mixed solvent containing 56 parts by mass of methyl ethyl ketone and 19 parts by mass of isopropyl alcohol was added 75 parts by mass of the copolymerized polyester resin 10, and the mixture was stirred at 65° C. to dissolve the copolymerized polyester resin 10 to thereby obtain a resin solution 11.

To the resin solution 11 was added 15 parts by mass of maleic anhydride to obtain a resin solution 12. Next, 10 parts by mass of styrene and 1.5 parts by mass of azobis dimethyl nitrile were dissolved in 12 parts by mass of methyl ethyl ketone to prepare a resin solution 13. To the resin solution 12 was added the resin solution 13 dropwise at a rate of 0.1 ml/min, and stirring was continued for 2 hours. Then, 5 parts by mass of methanol were added, and 300 parts by mass of water and 15 parts by mass of triethylamine were further added, and the mixture was stirred for 1 hour. The temperature of the reaction vessel was then raised to 100° C. Thereby, methyl ethyl ketone, isopropyl alcohol, and excessive triethylamine were distilled off to obtain resin 14 for easy adhesion.

The resin 14 for easy adhesion was dissolved in a mixed solvent obtained by mixing of methyl ethyl ketone and toluene at a mass ratio of 8:2 to obtain coating liquid D for the easily-adhesive layer with a solid content of 5 mass %. The mass ratio between the polyester component and the polyurethane component of the resin in the coating liquid D for the easily-adhesive layer is 5:5.

### 2-5. Coating Liquid E for Easily-Adhesive Layer

Coating liquid E for the easily-adhesive layer was obtained in the same manner as for the coating liquid A for the easily-adhesive layer, except that the amounts of dimethyl terephthalate, ethylene glycol, 1,4-butanediol, and m-xylene diisocyanate were changed to the following amounts. The mass ratio between the polyester component and the polyurethane component of the resin in the coating liquid E for the easily-adhesive layer is 2:8.
Dimethyl terephthalate 106 parts by mass
Ethylene glycol 25 parts by mass
1,4-Butanediol 25 parts by mass
m-Xylene diisocyanate 0.1 parts by mass

### 2-6. Coating Liquid F for Easily-Adhesive Layer

Coating liquid F for the easily-adhesive layer was obtained in the same manner as for the coating liquid A for the easily-adhesive layer, except that the amounts of dimethyl terephthalate, ethylene glycol, 1,4-butanediol, and m-xylene diisocyanate were changed to the following amounts. The mass ratio between the polyester component and the polyurethane component of the resin in the coating liquid F for the easily-adhesive layer is 88:12.
Dimethyl terephthalate 100 parts by mass
Ethylene glycol 21.5 parts by mass
1,4-Butanediol 21.5 parts by mass
m-Xylene diisocyanate 13 parts by mass

### 2-7. Coating Liquid G for Easily-Adhesive Layer

Coating liquid G for the easily-adhesive layer was obtained in the same manner as for the coating liquid A for the easily-adhesive layer, except that the amounts of dimethyl terephthalate, ethylene glycol, 1,4-butanediol, and m-xylene diisocyanate were changed to the following amounts. The mass ratio between the polyester component and the polyurethane component of the resin in the coating liquid G for the easily-adhesive layer is 83:17.
Dimethyl terephthalate 100 parts by mass
Ethylene glycol 23 parts by mass
1,4-Butanediol 23 parts by mass
m-Xylene diisocyanate 20 parts by mass

### 3. Production and Provision of PET Films, and Measurement or Calculation of In-Plane Phase Difference of Each PET Film, Etc.

The following PET films 1 to 6 were produced, and the following PET films 7 to 9 were provided, as polyester films of the Examples and Comparative Examples.

The in-plane phase difference (Re) of each PET film was measured using Otsuka Electronics' product name “RETS-100”. Then, nx−ny of each PET film was calculated by dividing the measured value of the in-plane phase difference of each PET film by the thickness of each PET film. The thickness of each PET film was measured using Nikon's product name “Digimicro” (“MS-5C+MH-15M” was used for the stand+main unit, and “TC-101A” for the counter).

### 3-1. PET Film 1

1 kg of PET (melting point 258° C., absorption center wavelength: 320 nm) and 0.1 kg of UV absorber (2,2′-(1,4-phenylene)bis(4H-3,1-benzoxazinone-4-one) were melt-mixed in a kneader at 280° C. to produce a pellet containing an UV absorber. The pellet and PET with a melting point of 258° C. were fed into a single screw extruder, melt-kneaded at 280° C., extruded through a T-die, and cast on a cast drum with a controlled surface temperature to obtain a casting film. The amount of UV absorber in the casting film was 3 parts by mass with respect to 100 parts by mass of PET. (Control of the surface temperature of the casting drum: 45° C. for the area where the resin extruded from the T-die adheres. The part of the resin peeling point is 23° C. The temperature is adjusted so that the temperature decreases gradually from the area where the resin adheres to the resin peeling point).

The resulting casting film was heated with a group of rolls set at 119° C. After that, the film was stretched 5.1 times in the flow direction while being heated from both the front and back sides by a radiant heater such that the film temperature at 180-mm point of the 480 mm stretching section (starting point was stretch roll A, ending point was stretch roll B; the stretch rolls A and B each had two nip rolls) was 138° C., and then cooled temporarily. The time for the casting film to pass through the stretching section in the flow direction was 0.194 seconds.

The uniaxially stretched film was then guided to a tenter, preheated with a group of rolls set at 119° C., and then stretched 4.9 times in the film width direction while being heat-treated with hot air at 105° C. in the first step and hot air at 140° C. in the second step. Here, when the transverse stretching section was divided into two sections, the film was stretched in two steps so that the amount of film stretching at the midpoint of the transverse stretching section (the film width at a measurement point−the film width before stretched) was 80% of the amount of stretching at the end of the transverse stretching section. The film stretched in the width direction was heat-treated, as it was, by hot air in the tenter stepwise from 180° C. to a heat-treatment temperature of 245° C. Next, 1% relaxation treatment was performed in the width direction at the same temperature conditions. After quenching to 100° C., 1% relaxation treatment was further performed in the width direction. Thereafter, the film was wound up to obtain a biaxially stretched PET film 1 with a thickness of 40 μm.

### 3-2. PET Film 2

A biaxially stretched PET film 2 was obtained in the same manner as for the PET film 1. The production conditions for the PET film 2 were the same as for the PET film 1, but its physical properties were slightly different from those of the PET film 1 due to lot variation.

### 3-3. PET Film 3

A biaxially stretched PET film 3 was obtained in the same manner as for the PET film 1, except that the time for the casting film to pass through the stretching section in the flow direction was changed to 0.179 seconds and the relaxation treatment after heat-treatment and the relaxation treatment after quenching were not performed.

### 3-4. PET Film 4

A biaxially stretched PET film 4 was obtained in the same manner as for the PET film 1, except that the time for the casting film to pass through the stretching section in the flow direction was changed to 0.185 seconds and the relaxation treatment after quenching was not performed.

### 3-5. PET Film 5

A biaxially stretched PET film 5 was obtained in the same manner as for the PET film 1. The production conditions for the PET film 5 were the same as for the PET film 1, but its physical properties were slightly different from those of the PET film 1 due to lot variation.

### 3-6. PET Film 6

A biaxially stretched PET film 6 was obtained in the same manner as for the PET film 1, except that the time for the casting film to pass through the stretching section in the flow direction was changed to 0.185 seconds and the relaxation treatment after quenching was not performed. The production conditions for the PET film 6 were the same as for the PET film 4, but its physical properties were slightly different from those of the PET film 4 due to lot variation.

### 3-7. PET Film 7

A commercially available biaxially stretched PET film (product name “COSMOSHINE A4160” manufactured by Toyobo; thickness: 38 μm; with an easily-adhesive layer on one side) was provided as a PET film 7.

### 3-8. PET Film 8

A commercially available biaxially stretched PET film (product name “COSMOSHINE A4160” manufactured by Toyobo; thickness: 38 μm; with an easily-adhesive layer on one side) was provided as a PET film 8.

### 3-9. PET Film 9

Polyethylene terephthalate was melted at 290° C., extruded through a film forming die into a sheet form, and cooled in close contact on a water-cooled rotating quenching drum to produce an unstretched film. The unstretched film was preheated at 160° C. for 150 seconds and then uniaxially stretched 5.2 times at 160° C. with a fixed end in a biaxial stretching test apparatus (Toyo Seiki Co., Ltd.) to produce a PET film with in-plane birefringence. The refractive indices of this PET film at a wavelength of 550 nm were nx=1.701 and ny=1.6015, and Δn=0.0995.

The film thickness of this PET film was adjusted to obtain a PET film 9, a uniaxially stretched PET film with an in-plane phase difference of 5174 nm.

### 4. Production of Easily-Adhesive Layer-Including Polyester Film and Optical Laminate

### Example 1

The above coating liquid A for the easily-adhesive layer was applied onto the PET film 1 and dried at 90° C. for 60 seconds to form an easily-adhesive layer with a thickness of 100 nm. In this way, an easily-adhesive layer-including polyester film of Example 1 was obtained.

Next, onto the easily-adhesive layer a coating liquid for a hard coating layer as formulated below was applied, dried at 80° C. for 60 seconds, and cured by irradiating with ultraviolet rays of 200 mJ/cm² to form a hard coating layer with a dry thickness of 8 μm. In this way, an optical laminate of Example 1 was obtained.

### <Coating Liquid for Hard Coating Layer>

Polyfunctional acrylate monomer 12 parts by mass

(NIPPON KAYAKU Co., Ltd.; product name: PET-30)
Polyfunctional acrylate oligomer 28 parts by mass

(Mitsubishi Chemical Corporation, product name: SHIKOH UV-1700B
Toluene 48 parts by mass
Methyl ethyl ketone 12 parts by mass

### Example 2

An optical laminate of Example 2 was obtained in the same manner as in Example 1, except that the PET film 1 was changed to the PET film 2 and the coating liquid A for the easily-adhesive layer was changed to the coating liquid B for the easily-adhesive layer.

### Example 3

An optical laminate of Example 3 was obtained in the same manner as in Example 1, except that the PET film 1 was changed to the PET film 3.

### Example 4

An optical laminate of Example 4 was obtained in the same manner as in Example 1, except that the PET film 1 was changed to the PET film 4.

### Example 5

An optical laminate of Example 5 was obtained in the same manner as in Example 1, except that the coating liquid A for the easily-adhesive layer was changed to the coating liquid F for the easily-adhesive layer.

### Example 6

An optical laminate of Example 6 was obtained in the same manner as in Example 1, except that the coating liquid A for the easily-adhesive layer was changed to the coating liquid G for the easily-adhesive layer.

### Comparative Example 1

An optical laminate of Comparative Example 1 was obtained in the same manner as in Example 1, except that the PET film 1 was changed to the PET film 5, the coating liquid A for the easily-adhesive layer was changed to the coating liquid C for the easily-adhesive layer, and the conditions of drying the easily-adhesive layer were changed to 90° C. for 120 seconds.

### Comparative Example 2

An optical laminate of Comparative Example 2 was obtained in the same manner as in Example 1, except that the PET film 1 was changed to the PET film 6 and the coating liquid A for the easily-adhesive layer was changed to the coating liquid E for the easily-adhesive layer.

### Comparative Example 3

An optical laminate of Comparative Example 3 was obtained in the same manner as in Example 1, except that the PET film 1 was changed to the PET film 7. Note that the easily-adhesive layer and the hard coating layer were formed on a side opposite to the preformed easily-adhesive layer.

### Comparative Example 4

An optical laminate of Comparative Example 4 was obtained in the same manner as in Example 1, except that the PET film 1 was changed to the PET film 8 and the coating liquid A for the easily-adhesive layer was changed to the coating liquid D for the easily-adhesive layer. Note that the easily-adhesive layer and the hard coating layer were formed on a side opposite to the preformed easily-adhesive layer.

### Comparative Example 5

An optical laminate of Comparative Example 5 was obtained in the same manner as in Example 1, except that the PET film 1 was changed to the PET film 9 and the coating liquid A for the easily-adhesive layer was changed to the coating liquid E for the easily-adhesive layer.

### Comparative Example 6

An optical laminate of Comparative Example 6 was obtained in the same manner as in Example 1, except that the conditions of drying the easily-adhesive layer were changed to 25° C. for 180 seconds. Note that in Comparative Example 6, the easily-adhesive layer was dried slowly, so that the thickness of the easily-adhesive layer was uneven. In the measurements of 1-2 above, the areas with small irregularities were used for evaluation so that no extreme uneven shapes were included within the seven measurement regions.

TABLE 1

| | | | Coating | | | | | | | | |
|---|---|---|---|---|---|---|---|---|---|---|---|
| | | | liquid for | | | | Coefficient | | | | |
| | | | easily- | | | Average | of | | Pencil hardness | | |
| | | PET | adhesive | Tt | Hz | value of | variation | | Slow | Fast | Total |
| | | film | layer | (%) | (%) | δq/δa | δq/δa | Adhesion | axis | axis | evaluation |
| Example | 1 | 1 | A | 90.2 | 0.4 | 1.326 | 0.034 | A | F | F | AA |
| | 2 | 2 | B | 90.1 | 0.5 | 1.536 | 0.039 | B | F | F | A |
| | 3 | 3 | A | 90.2 | 0.5 | 1.339 | 0.018 | A | B | B | A |
| | 4 | 4 | A | 90.1 | 0.5 | 1.339 | 0.024 | A | F | F | AA |
| | 5 | 1 | F | 90.1 | 0.1 | 1.125 | 0.009 | B | F | F | A |
| | 6 | 1 | G | 90.2 | 0.2 | 1.295 | 0.030 | A | F | F | AA |
| Comparative | 1 | 5 | C | 90.1 | 0.6 | 1.614 | 0.031 | C | F | F | C |
| Example | 2 | 6 | E | 90.1 | 0.5 | 2.598 | 0.083 | C | B | B | C |
| | 3 | 7 | A | 90.1 | 0.5 | 1.403 | 0.071 | A | 3B | 3B | C |
| | 4 | 8 | D | 90.2 | 0.5 | 1.740 | 0.105 | A | 3B | 3B | C |
| | 5 | 9 | E | 90.1 | 0.4 | 2.278 | 0.258 | A | 2B | 3B | C |
| | 6 | 1 | A | 90.1 | 0.8 | 2.189 | 0.077 | C | F | F | C |

TABLE 2

| | | Re | E₀₋₂₀ | σ₀₋₂₀/ | Rainbow |
|---|---|---|---|---|---|
| PET film | nx − ny | [nm] | [μm/g] | E₀₋₂₀ | uneveness |
| 1 | 0.013 | 497 | 2.07 | 0.040 | AA |
| 2 | 0.013 | 535 | 2.05 | 0.042 | AA |
| 3 | 0.029 | 1148 | 1.78 | 0.077 | B |
| 4 | 0.024 | 976 | 1.89 | 0.059 | A |
| 5 | 0.014 | 541 | 2.04 | 0.044 | AA |
| 6 | 0.026 | 995 | 1.96 | 0.052 | B⁺ |
| 7 | 0.039 | 1486 | 1.01 | 0.115 | C |
| 8 | 0.040 | 1501 | 1.05 | 0.108 | C |
| 9 | 0.103 | 5174 | 1.29 | 0.111 | C |

The results of Tables 1 to 2 have demonstrated that the easily-adhesive layer-including polyester films of the Examples 1 to 6 can be used to achieve favorable adhesion of an optical laminate including, in sequence, a polyester film with a high pencil hardness, an easily-adhesive layer, and a functional layer. The easily-adhesive layer-including polyester film of Example 2 did not have better adhesion than the other Examples because the average value of δq/δa was larger than the other Examples. The reason why the average value of δq/δa in Example 2 is larger than that in the other Examples may be due to the larger ratio of polyurethane component in the easily-adhesive layer than in the other Examples. The easily-adhesive layer-including polyester film of Example 5 did not have better adhesion than the other Examples because the average value of δq/δa was smaller than the other Examples. Since the components of the easily-adhesive layer in Example 5 are similar to polyester alone, the viscoelasticity of the easily-adhesive layer is closer to be even, and the average value of δq/δa is thus considered to be smaller.

The results of Tables 1 to 2 have demonstrated that when the easily-adhesive layer-including polyester films of Comparative Examples 1 to 2 and 6 were used, it was impossible to impart favorable adhesion to an optical laminate including, in sequence, a polyester film with a high pencil hardness, an easily-adhesive layer, and a functional layer. The reason for this is that the pencil hardness of the polyester film in each of the easily-adhesive layer-including polyester films in Comparative Examples 1 to 2 and 6 is B or higher and the average value of δq/δa exceeds 1.60. The reason why the average value of δq/δa in Comparative Example 1 exceeds 1.60 may be because the coating liquid for the easily-adhesive layer is water-based, which takes time to dry, and the resin component of the easily-adhesive layer is polyurethane. The reason why the average value of δq/δa in Comparative Example 2 exceeds 1.60 may be because the coating liquid for the easily-adhesive layer contains polyurethane and polyester components as resin components, but the ratio of polyurethane component is high. The reason why the average value of δq/δa in Comparative Example 6 exceeds 1.60 may be because it takes time for the coating liquid for the easily-adhesive layer to dry.

The easily-adhesive layer-including polyester films of Comparative Examples 3 to 5 had favorable adhesion, but the polyester films had a pencil hardness of less than B. Therefore, the surface of the functional layer of the corresponding optical laminate, or the polyester film itself, was easily scratched.

Although not shown in Table 1, the contact angles of the optical laminates of Examples 1 to 4 to pure water on the surface on the hard coating layer side were all 90 degrees.

In addition, the results of Tables 1 to 2 have demonstrated that the PET films 1 to 6 with an average erosion rate (E₀₋₂₀) of 1.4 μm/g or more can easily achieve a pencil hardness of B or higher.

### REFERENCE SIGNS LIST

100: Polyester film
200: Easily-adhesive layer
300: Functional layer
1000: Optical laminate
11: Container
12: Receptor
21: Piping for test solution
22: Compressed air line
23: Return piping
24: Return pump
31, 32: Flowmeter
41, 42: Pressure gauge
50: Jetting section
51: Nozzle
52: Housing
60: Cross-sectional profile acquisition unit
70: Polyester film
81: Sample mount
82: Support
90: Erosion rate measuring device
A1: Water
A2: Spherical silica
A3: Air
A4: Abraded polyester film

1. An easily-adhesive layer-including polyester film comprising an easily-adhesive layer on a polyester film, wherein the polyester film has a pencil hardness of B or higher, and an average value of δq/δa of a surface of the easily-adhesive layer is 1.60 or less:
<calculation of average value of δq/δa>
a 10 μm×10 μm area of the surface of the easily-adhesive layer is measured using an atomic force microscope in a phase mode; a distribution of phase signal on the surface of the easily-adhesive layer is obtained from the measurement; the unit of the phase signal is [deg];
an arithmetic mean value of the phase signal as shown in Equation 1 below is denoted as δa; a root mean square of the phase signal as shown in Equation 2 below is denoted as δq;
(In Equations 1 and 2 below, in the case where the orthogonal coordinate axes X and Y are placed on the reference surface showing the average value of the phase signal, and the axis orthogonal to the reference surface is the Z axis, the surface of the phase signal is defined as f(x, y); in Equations 1 and 2 below, the sizes of the area in which δa and δq are calculated are set as Lx and Ly; in Equations 1 and 2 below, Ar=Lx×Ly);
seven 2 μm×2 μm measurement evaluation regions are selected from within the 10 μm×10 μm measurement area; δa, δq, and δq/δa are calculated for each of the seven measurement evaluation regions; and the average value of δq/δa is calculated based on the δq/δa of five locations, excluding the maximum and minimum values from the δq/δa of the seven locations.
$$\begin{matrix}[ Equation 1 ] & \\ δ a = \frac{1}{Ar} {\int }_{0}^{Lx} {\int }_{0}^{Ly} \vert f ( x , y ) \vert dxdy & Equation 1\end{matrix}$$
$$\begin{matrix}[ Equation 2 ] & \\ δ q = \sqrt{\frac{1}{Ar} {\int }_{0}^{Lx} {\int }_{0}^{Ly} {f}^{2} ( x , y ) dxdy} & Equation 2\end{matrix}$$

2. The easily-adhesive layer-including polyester film according to claim 1, wherein a coefficient of variation of δq/δa as calculated based on the δq/δa of the five locations is 0.040 or less.

3. The easily-adhesive layer-including polyester film according to claim 1, wherein when a refractive index in a direction of a slow axis in a plane of the polyester film is defined as nx and a refractive index in a direction perpendicular to the slow axis in the same plane is defined as ny, the nx and the ny satisfy the following relationship:
nx−ny≤0.0250.

4. The easily-adhesive layer-including polyester film according to claim 1, wherein a thickness of the polyester film is 10 μm or more and 75 μm or less.

5. The easily-adhesive layer-including polyester film according to claim 1, wherein when E₀₋₂₀ is defined as an average erosion rate from a surface of the polyester film to a depth of 20 μm, the E₀₋₂₀ of the polyester film is 1.4 μm/g or more.

6. An optical laminate comprising one or more functional layers on the easily-adhesive layer of the polyester film according to claim 1.

7. The optical laminate according to claim 6, wherein a functional layer in contact with the easily-adhesive layer among the one or more functional layers comprises a cured product of an ionizing radiation curable resin composition.

8. The optical laminate according to claim 6, wherein a surface of the optical laminate on the functional layer side has a contact angle to pure water of 80 degrees or more.

9. A polarizing plate comprising: a polarizer; a first transparent protective plate disposed on one side of the polarizer, and a second transparent protective plate disposed on the other side of the polarizer, wherein at least one of the first transparent protective plate or the second transparent protective plate is the optical laminate according to claim 6, and wherein the optical laminate is arranged so that a surface on the functional layer side faces a side opposite to the polarizer.

10. A surface plate comprising an optical laminate laminated on a resin plate or a glass plate, wherein the optical laminate is the optical laminate according to claim 6, and wherein the optical laminate is arranged so that a surface on the functional layer side faces a side opposite to the resin plate or the glass plate.

11. An image display panel comprising the optical laminate according to claim 6 arranged on a display element.

12. An image display device comprising the image display panel according to claim 11.
